(19) United States
(12) Patent Application Publication
(10) Pub. No.: US 2026/0068348 A1
(43) Pub. Date: Mar. 5, 2026

(54) SEMICONDUCTOR LIGHT-EMITTING DEVICE

(71) Applicant: ROHM CO., LTD., Kyoto (JP)

(72) Inventor: Okimoto KONDO, Kyoto-shi (JP)

(73) Assignee: ROHM CO., LTD., Kyoto (JP)

(21) Appl. No.: 19/384,669

(22) Filed: Nov. 10, 2025

Related U.S. Application Data
(63) Continuation of application No. PCT/JP2024/009651, filed on Mar. 12, 2024.

(30) Foreign Application Priority Data
May 19, 2023 (JP) 2023-082727

(51) Int. Cl. H10F 55/00; H10F 77/00; H10F 77/40; H10F 77/50

(52) U.S. Cl. CPC H10F 55/18; H10F 77/413; H10F 77/50; H10F 77/933

(57) ABSTRACT

The semiconductor light-emitting device includes: a substrate; a light-receiving chip that includes a light-receiving element having a light-receiving surface formed on the chip surface; an edge-emitting chip that has a first light-emitting surface that emits first laser beam and a second light-emitting surface that emits second laser beam in an opposite direction, and that is joined to a position different from the light-receiving surface on the chip surface; a sealing member with a material through which the first and second laser beams can pass, the sealing member covering the edge-emitting chip and the light-receiving chip; and a reflection part provided in the sealing member and that reflects at least a portion of the second laser beam toward the light-receiving surface. The light-receiving surface is formed in a position on the chip surface for receiving at least a part of the reflected light by the reflection part.

### CROSS-REFERENCE TO RELATED APPLICATIONS

This application is a continuation of, and claims the benefit of priority from International Application No. PCT/JP2024/009651, filed on March 12, 2024, which claims the benefit of priority from Japanese Patent Application No. 2023-82727, filed on May 19, 2023, the entire contents of each are incorporated herein by reference.

### BACKGROUND

### 1. Field

The following description relates to a semiconductor light-emitting device.

### 2. Description of Related Art

A typical semiconductor light-emitting device (for example, JP2013-41866A) that includes a light-emitting diode (LED) as a light source may be used in various types of electronic devices.

### BRIEF DESCRIPTION OF THE DRAWINGS

FIG. 1 is a schematic perspective view of a semiconductor light-emitting device in accordance with a first embodiment.

FIG. 2 is a schematic plan view of the semiconductor light-emitting device shown in FIG. 1 in a state in which an encapsulant is omitted.

FIG. 3 is a schematic cross-sectional view of the semiconductor light-emitting device taken along line F3-F3 shown in FIG. 2.

FIG. 4 is a schematic cross-sectional view of a semiconductor light-emitting device in accordance with a second embodiment.

FIG. 5 is a schematic plan view of a semiconductor light-emitting device in accordance with a third embodiment in a state in which an encapsulant is omitted.

FIG. 6 is a schematic cross-sectional view of the semiconductor light-emitting device taken along line F6-F6 shown in FIG. 5.

FIG. 7 is a schematic cross-sectional view of a semiconductor light-emitting device in accordance with a fourth embodiment.

FIG. 8 is a schematic cross-sectional view of a semiconductor light-emitting device in accordance with a fifth embodiment.

FIG. 9 is a schematic cross-sectional view of a semiconductor light-emitting device in accordance with a sixth embodiment.

FIG. 10 is a schematic cross-sectional view of a semiconductor light-emitting device in accordance with a seventh embodiment.

FIG. 11 is a schematic cross-sectional view of a semiconductor light-emitting device in accordance with an eighth embodiment.

FIG. 12 is a schematic cross-sectional view of a semiconductor light-emitting device in accordance with a ninth embodiment.

FIG. 13 is a schematic cross-sectional view of a semiconductor light-emitting device in accordance with a modified example.

FIG. 14 is a schematic cross-sectional view of a semiconductor light-emitting device in accordance with a modified example.

FIG. 15 is a schematic cross-sectional view of a semiconductor light-emitting device in accordance with a modified example.

FIG. 16 is a schematic cross-sectional view of a semiconductor light-emitting device in accordance with a modified example.

FIG. 17 is a schematic cross-sectional view of a semiconductor light-emitting device in accordance with a modified example.

FIG. 18 is a schematic cross-sectional view of a semiconductor light-emitting device in accordance with a modified example.

FIG. 19 is a schematic cross-sectional view of a semiconductor light-emitting device in accordance with a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Several embodiments of a semiconductor light-emitting device will now be described with reference to the accompanying drawings. Elements in the drawings are illustrated for simplicity and clarity and are not necessarily drawn to scale. In the cross-sectional drawings, hatching lines may not be shown in order to facilitate understanding. The accompanying drawings merely illustrate exemplary embodiments of the present disclosure and are not intended to limit the present disclosure.

The following detailed description provides exemplary embodiments of methods, apparatuses, and/or systems in accordance with the present disclosure. This detailed description is illustrative and is not intended to limit embodiments of the present disclosure or the application and use of the embodiments.

### First Embodiment

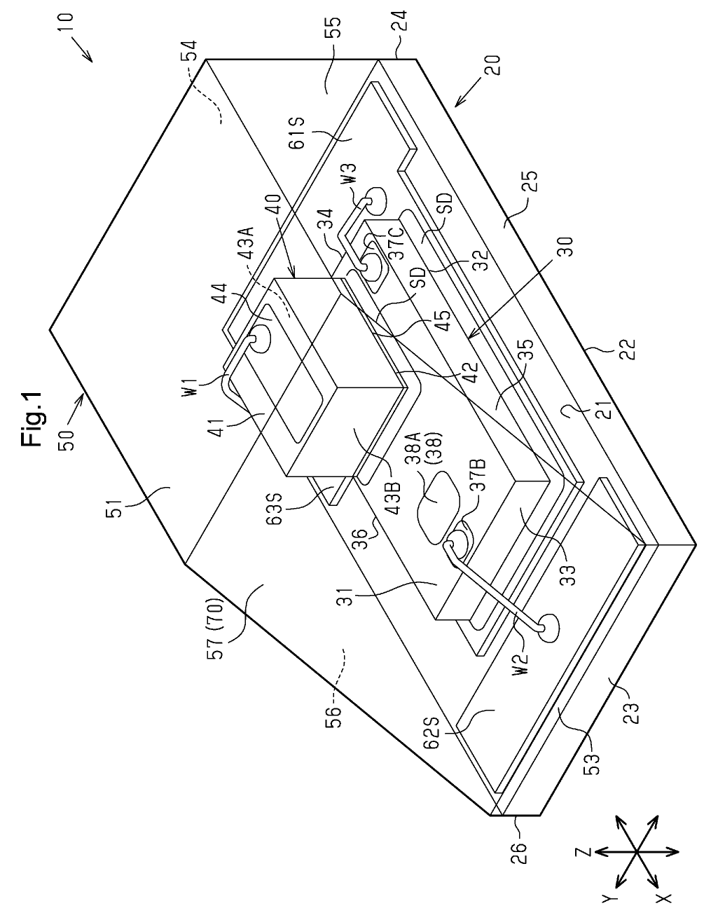

A semiconductor light-emitting device 10 in accordance with a first embodiment will now be described with reference to FIGS. 1 to 3.

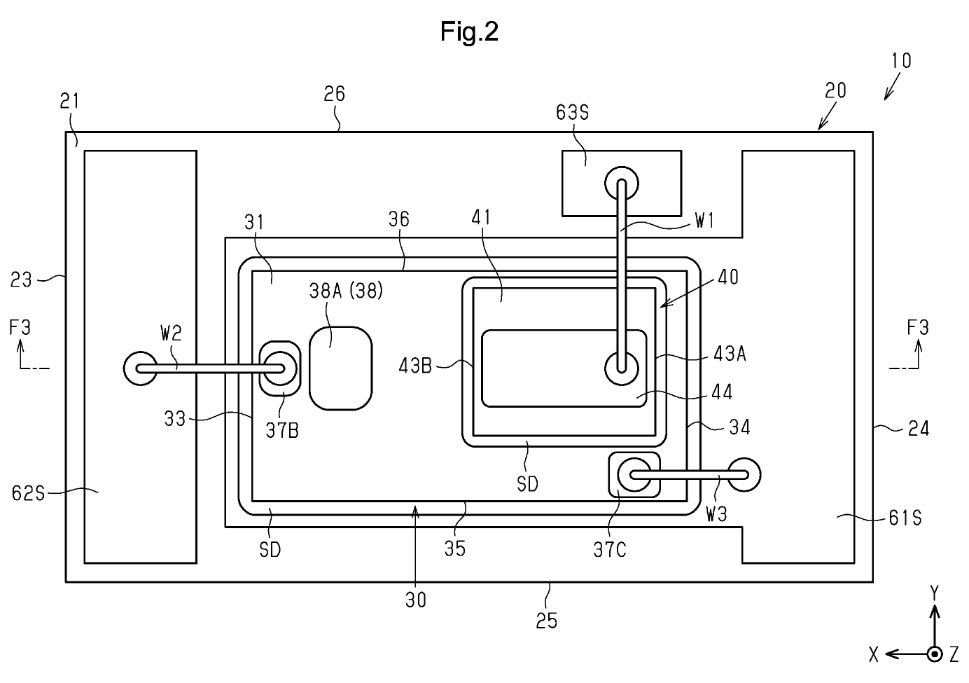

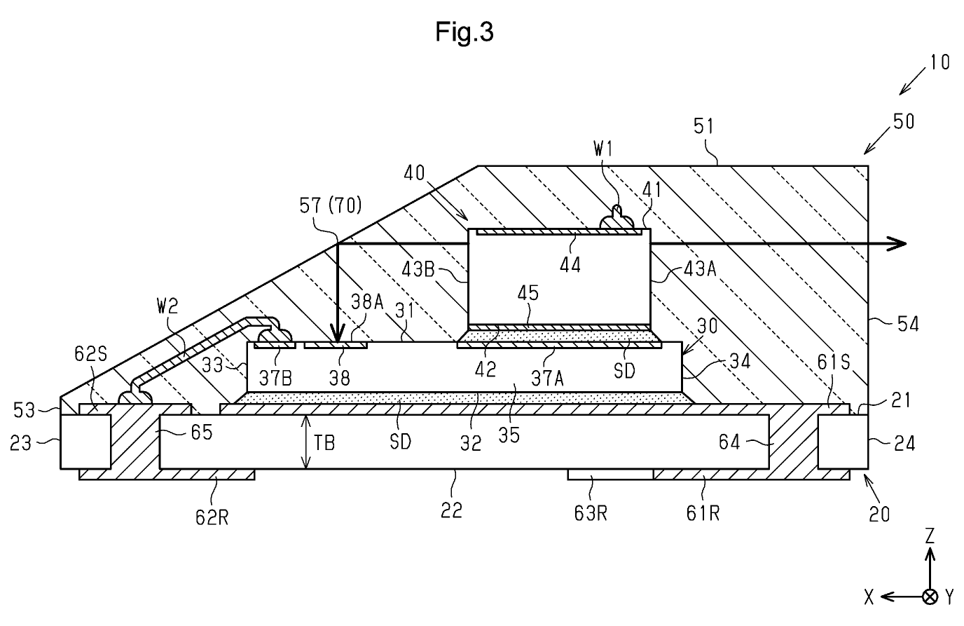

FIG. 1 is a schematic perspective view showing the structure of the semiconductor light-emitting device 10. FIG. 2 is a schematic plan view showing the internal structure of the semiconductor light-emitting device 10 by omitting an encapsulant 50, which will be described later. FIG. 3 shows a schematic cross-sectional structure of the semiconductor light-emitting device 10 taken along line F3-F3 shown in FIG. 2. In this disclosure, X-axis, Y-axis, and Z-axis are orthogonal to one another as shown in FIG. 1. The term “plan view” as used in this specification refers to a view of the semiconductor light-emitting device 10 taken in the Z-direction.

As shown in FIG. 1, the semiconductor light-emitting device 10 includes a substrate 20, a light-receiving chip 30 arranged on the substrate 20, an edge-emitting chip 40 arranged on the light-receiving chip 30, and an encapsulant 50 encapsulating at least part of the light-receiving chip 30 and at least part of the edge-emitting chip 40. The encapsulant 50 is an example of a cover.

The substrate 20 is a component that supports the light-receiving chip 30. The substrate 20 has a shape of a rectangular plate having a thickness-wise direction parallel to the Z-direction. In the description hereafter, the phrase “in plan view” is synonymous with “as viewed in the thickness-wise direction of the substrate”.

As shown in FIG. 2, the substrate 20 is rectangular in plan view, with long sides extending in the X-direction and short sides extending in the Y-direction. As shown in FIG. 1, the substrate 20 includes a substrate front surface 21, a substrate back surface 22 opposite to the substrate front surface 21 in the Z-direction, and first to fourth substrate side surfaces 23 to 26 (refer to FIG. 2) connecting the substrate front surface 21 and the substrate back surface 22. The first substrate side surface 23 and the second substrate side surface 24 are two end surfaces of the substrate 20 in the X-direction. The third substrate side surface 25 and the fourth substrate side surface 26 are two end surfaces of the substrate 20 in the Y-direction. The planar shape of the substrate 20 may be changed.

The substrate 20 is formed from, for example, an insulative material. The insulative material may be, for example, a material containing an epoxy resin. In an example, the substrate 20 may be formed from a glass epoxy resin. The insulative material may be, for example, a material containing ceramic. Examples of the material containing ceramic may include aluminum nitride (AlN), alumina (Al₂O₃), and the like. When the substrate 20 is formed from the material containing ceramic, the substrate 20 has improved heat dissipation performance, so that the temperature of the semiconductor light-emitting device 10 will not become excessively high.

As shown in FIG. 1, the light-receiving chip 30 has a shape of a rectangular plate having a thickness-wise direction parallel to the Z-direction. The light-receiving chip 30 includes a chip front surface 31 and a chip back surface 32 facing opposite directions with respect to the Z-direction, and first to fourth chip side surfaces 33 to 36 connecting the chip front surface 31 and the chip back surface 32. The first chip side surface 33 and the second chip side surface 34 are two end surfaces of the light-receiving chip 30 in the X-direction. The third chip side surface 35 and the fourth chip side surface 36 are two end surfaces of the light-receiving chip 30 in the Y-direction. The chip front surface 31 faces the same direction as the substrate front surface 21. The chip back surface 32 faces the same direction as the substrate back surface 22. The first chip side surface 33 faces the same direction as the first substrate side surface 23. The second chip side surface 34 faces the same direction as the second substrate side surface 24. The third chip side surface 35 faces the same direction as the third substrate side surface 25. The fourth chip side surface 36 faces the same direction as the fourth substrate side surface 26.

As shown in FIGS. 2 and 3, the light-receiving chip 30 includes a first electrode 37A, a second electrode 37B, a third electrode 37C, and a light-receiving element 38. The first to third electrodes 37A to 37C and the light-receiving element 38 are formed in the chip front surface 31.

In plan view, the light-receiving element 38 is formed in the chip front surface 31 at a position located relatively close to the first chip side surface 33. The light-receiving element 38 includes, for example, a photodiode. The light-receiving element 38 includes a light-receiving surface 38A. The light-receiving surface 38A is formed in the chip front surface 31. In other words, the light-receiving surface 38A is exposed from the chip front surface 31.

The light-receiving element 38 further includes a first element electrode and a second element electrode. The first element electrode serves as one of an anode and a cathode of the photodiode, and the second element electrode serves as the other one of the anode and the cathode of the photodiode. In the first embodiment, the first element electrode is the anode, and the second element electrode is the cathode. The first element electrode of the light-receiving element 38 is electrically connected to the second electrode 37B inside the light-receiving chip 30. The second element electrode of the light-receiving element 38 is electrically connected to the third electrode 37C inside the light-receiving chip 30.

In plan view, the first electrode 37A is formed in the chip front surface 31 at a position located relatively close to the second chip side surface 34. The first electrode 37A is an electrode that receives the edge-emitting chip 40. In plan view, the first electrode 37A is larger than each of the second electrode 37B and the third electrode 37C.

In plan view, the second electrode 37B is formed in the chip front surface 31 at one of the two ends in the X-direction that is located closer to the first chip side surface 33. In plan view, the second electrode 37B is located substantially at the center of the chip front surface 31 in the Y-direction. The second electrode 37B is electrically connected to the light-receiving element 38. The position of the second electrode 37B may be changed with respect to the X-direction or the Y-direction.

In plan view, the third electrode 37C is formed in the chip front surface 31 at one of the two ends in the X-direction that is located closer to the second chip side surface 34. In plan view, the third electrode 37C is formed in the chip front surface 31 at one of the two ends in the Y-direction that is located closer to the third chip side surface 35. The third electrode 37C is electrically connected to the first electrode 37A inside the light-receiving chip 30. The position of the third electrode 37C may be changed with respect to the X-direction or the Y-direction.

The edge-emitting chip 40 is a laser diode configured to emit a laser beam in a predetermined wavelength band. The edge-emitting chip 40 acts as a light source of the semiconductor light-emitting device 10. The edge-emitting chip 40 may be, for example, an edge-emitting laser (EEL). In this case, the laser beam may be a visible light ray. Alternatively, the laser beam may be a light ray having a longer wavelength than a visible light ray, such as an ultraviolet ray or the like.

The edge-emitting chip 40 is box-shaped. In an example, as shown in FIG. 2, the edge-emitting chip 40 is rectangular in plan view, with long sides extending in the X-direction and short sides extending in the Y-direction. The planar shape of the edge-emitting chip 40 may be changed.

As shown in FIG. 1, the edge-emitting chip 40 includes a first front surface 41 and a first back surface 42 facing opposite directions with respect to the Z-direction, and four side surfaces connecting the first front surface 41 and the first back surface 42. Ones of the four side surfaces that form two end surfaces in the X-direction correspond to a first light-emitting surface 43A and a second light-emitting surface 43B. As shown in FIG. 3, the first light-emitting surface 43A and the second light-emitting surface 43B are both flat surfaces orthogonal to the first front surface 41 (first back surface 42). The first light-emitting surface 43A and the second light-emitting surface 43B face away from each other. The first light-emitting surface 43A is configured to emit a first laser beam in the X-direction. The X-direction is an example of a first direction that intersects the Z-direction in plan view. In other words, the first light-emitting surface 43A is configured to emit the first laser beam toward a second encapsulant side surface 54 of the encapsulant 50. The second light-emitting surface 43B is configured to emit a second laser beam in a direction opposite to the emission direction of the first laser beam in plan view. In other words, the second light-emitting surface 43B is configured to emit the second laser beam in a direction opposite to the second encapsulant side surface 54, that is, in a direction toward a first encapsulant side surface 53 of the encapsulant 50.

In the first embodiment, an end-face coating (not shown) is formed on each of the first light-emitting surface 43A and the second light-emitting surface 43B. The end-face coating may include an insulative reflection coating. The end-face coating may include an insulative anti-reflection coating (AR coating). The end-face coating including the reflection coating may have an adjusted reflectance. In an example, the end-face coating of the second light-emitting surface 43B may be adjusted to have a higher reflectance than the end-face coating of the first light-emitting surface 43A. Accordingly, the intensity of the second laser beam emitted from the second light-emitting surface 43B is lower than that of the first laser beam emitted from the first light-emitting surface 43A. For example, the second laser beam may be a laser beam that leaks out of the second light-emitting surface 43B when the edge-emitting chip 40 emits the first laser beam.

The edge-emitting chip 40 includes a first front-surface electrode 44 formed in the first front surface 41, and a first back-surface electrode 45 formed in the first back surface 42. As shown in FIG. 2, in plan view, the first front-surface electrode 44 is located substantially at the center of the first front surface 41 in the Y-direction. The first front-surface electrode 44 is rectangular in plan view, with long sides extending in the X-direction and short sides extending in the Y-direction. As shown in FIG. 3, the first back-surface electrode 45 is formed in the entire first back surface 42.

As shown in FIG. 1, the encapsulant 50 is arranged on the substrate 20. The encapsulant 50 is formed from a material that allows passage of the first laser beam and the second laser beam from the edge-emitting chip 40. The encapsulant 50 is formed from, for example, a material containing at least one of a silicone resin, an epoxy resin, and an acrylic resin. In an example, the encapsulant 50 is formed from a silicone resin. In the first embodiment, the encapsulant 50 encapsulates the entire light-receiving chip 30 and the entire edge-emitting chip 40.

The encapsulant 50 has a thickness-wise direction parallel to the Z-direction. The encapsulant 50 has a shape of a substantially rectangular plate with a cut-out portion. The encapsulant 50 includes the encapsulant front surface 51 facing the same direction as the substrate front surface 21, and first to fourth encapsulant side surfaces 53 to 56 intersecting the encapsulant front surface 51.

The encapsulant front surface 51 is a flat surface orthogonal to the thickness-wise direction of the substrate 20 (Z-direction). Therefore, the phrase “in plan view” may be synonymous with “as viewed in a direction orthogonal to the encapsulant front surface 51”. The first to fourth encapsulant side surfaces 53 to 56 are, for example, orthogonal to the encapsulant front surface 51. The first encapsulant side surface 53 and the second encapsulant side surface 54 are two end surfaces of the encapsulant 50 in the X-direction. The third encapsulant side surface 55 and the fourth encapsulant side surface 56 are two end surfaces of the encapsulant 50 in the Y-direction. The first encapsulant side surface 53 faces the same direction as the first substrate side surface 23. The second encapsulant side surface 54 faces the same direction as the second substrate side surface 24. The third encapsulant side surface 55 faces the same direction as the third substrate side surface 25. The fourth encapsulant side surface 56 faces the same direction as the fourth substrate side surface 26. In an example, the first encapsulant side surface 53 is flush with the first substrate side surface 23. The second encapsulant side surface 54 is flush with the second substrate side surface 24. The third encapsulant side surface 55 is flush with the third substrate side surface 25. The fourth encapsulant side surface 56 is flush with the fourth substrate side surface 26. The first laser beam of the edge-emitting chip 40 is emitted through the encapsulant 50 out of the second encapsulant side surface 54.

### Electrical Configuration of Semiconductor Light-Emitting Device

As shown in FIGS. 2 and 3, the semiconductor light-emitting device 10 includes a first front-surface electrode 61S, a second front-surface electrode 62S, a third front-surface electrode 63S, a first back-surface electrode 61R, a second back-surface electrode 62R, a third back-surface electrode 63R, a first via 64, a second via 65, and a third via (not shown). The first to third front-surface electrodes 61S to 63S are included in the substrate front surface 21. The first to third back-surface electrodes 61R to 63R are included in the substrate back surface 22. The vias are arranged inside the substrate 20. The first to third front-surface electrodes 61S to 63S, the first to third back-surface electrodes 61R to 63R, the first via 64, the second via 65, and the third via are, for example, formed from a material containing one or more selected from titanium (Ti), titanium nitride (TiN), gold (Au), silver (Ag), copper (Cu), aluminum (Al), and tungsten (W).

As shown in FIG. 2, in plan view, the first front-surface electrode 61S extends from the second substrate side surface 24 toward the first substrate side surface 23 in the X-direction. In the example shown in FIG. 2, the first front-surface electrode 61S is substantially T-shaped in plan view.

The second front-surface electrode 62S is rectangular in plan view, with long sides extending in the Y-direction and short sides extending in the X-direction. The second front-surface electrode 62S is separated from the first front-surface electrode 61S in the X-direction. In plan view, the second front-surface electrode 62S is adjacent to the first substrate side surface 23 in the X-direction.

The third front-surface electrode 63S is rectangular in plan view, with long sides extending in the X-direction and short sides extending in the Y-direction. In plan view, the third front-surface electrode 63S is adjacent to the fourth substrate side surface 26 in the Y-direction, and is located closer to the second substrate side surface 24 than the center of the substrate front surface 21 in the X-direction is. The third front-surface electrode 63S is separated from both the first front-surface electrode 61S and the second front-surface electrode 62S.

The light-receiving chip 30 is arranged on the first front-surface electrode 61S. More specifically, as shown in FIG. 3, the light-receiving chip 30 is bonded to the first front-surface electrode 61S by a conductive bonding material SD. The conductive bonding material SD may be, for example, solder paste, silver paste, gold paste, copper paste, or the like.

As shown in FIG. 2, in plan view, the edge-emitting chip 40 is bonded to the chip front surface 31 at a position different from the light-receiving surface 38A. The edge-emitting chip 40 is arranged on the chip front surface 31 at a position located closer to the second chip side surface 34 than the light-receiving surface 38A is. As shown in FIG. 3, the edge-emitting chip 40 is, for example, bonded to the first electrode 37A by the conductive bonding material SD. Therefore, the first back-surface electrode 45 of the edge-emitting chip 40 is electrically connected to the first electrode 37A through the conductive bonding material SD.

As shown in FIG. 2, a wire W1 is formed on the first front-surface electrode 44 of the edge-emitting chip 40. The wire W1 is connected to the third front-surface electrode 63S. Therefore, the first front-surface electrode 44 of the edge-emitting chip 40 is electrically connected to the third front-surface electrode 63S through the wire W1. In the example shown in FIG. 2, the wire W1 extends in the Y-direction in plan view.

A wire W2 is formed on the second electrode 37B of the light-receiving chip 30. The wire W2 is connected to the second front-surface electrode 62S. Therefore, the first element electrode of the light-receiving element 38 is electrically connected to the second front-surface electrode 62S through the second electrode 37B and the wire W2. In the example shown in FIG. 2, the wire W2 extends in the X-direction in plan view.

A wire W3 is formed on the third electrode 37C of the light-receiving chip 30. The wire W3 is connected to the first front-surface electrode 61S. Therefore, the third electrode 37C is electrically connected to the first front-surface electrode 61S through the wire W3. The third electrode 37C is electrically connected to the first back-surface electrode 45 of the edge-emitting chip 40 and the second element electrode of the light-receiving element 38. Therefore, the first back-surface electrode 45 of the edge-emitting chip 40 and the second element electrode of the light-receiving element 38 are electrically connected to the first front-surface electrode 61S through the third electrode 37C and the wire W3. The wire W3 extends in the X-direction in plan view. The wires W1 to W3 are bonding wires formed by a wire bonder, and are formed from a conductor containing, for example, Au, Al, Cu, or the like. In the first embodiment, the wires W1 to W3 are encapsulated by the encapsulant 50.

As shown in FIG. 3, the first back-surface electrode 61R is formed in the substrate back surface 22 at one of the two ends in the X-direction that is located closer to the second substrate side surface 24. In plan view, the first back-surface electrode 61R has a portion overlapping the first front-surface electrode 61S.

The second back-surface electrode 62R is formed in the substrate back surface 22 at one of the two ends in the X-direction that is located closer to the first substrate side surface 23. In plan view, the second back-surface electrode 62R has a portion overlapping the second front-surface electrode 62S.

The third back-surface electrode 63R is located closer to the second substrate side surface 24 than the center of the substrate back surface 22 in the X-direction is. In plan view, the third back-surface electrode 63R has a portion overlapping the third front-surface electrode 63S (refer to FIG. 2).

The first via 64 electrically connects the first front-surface electrode 61S and the first back-surface electrode 61R. The second via 65 electrically connects the second front-surface electrode 62S and the second back-surface electrode 62R. Although not shown in the drawings, the third via electrically connects the third front-surface electrode 63S and the third back-surface electrode 63R. The first via 64, the second via 65, and the third via each extend through the substrate 20 in the Z-direction. Each of the first via 64, the second via 65, and the third via may include multiple vias.

The first back-surface electrode 61R is electrically connected to both the first back-surface electrode 45 of the edge-emitting chip 40 and the second element electrode of the light-receiving element 38 through the first via 64 and the first front-surface electrode 61S. The second back-surface electrode 62R is electrically connected to the first element electrode of the light-receiving element 38 through the second via 65 and the second front-surface electrode 62S. The third back-surface electrode 63R is electrically connected to the first front-surface electrode 44 of the edge-emitting chip 40 through the third via and the third front-surface electrode 63S. In this manner, the semiconductor light-emitting device 10 is structured as a surface-mount type package.

The semiconductor light-emitting device 10 may be controlled in accordance with an auto power control (APC) drive. The APC drive controls a current supplied to the edge-emitting chip 40, so that the first laser beam and the second laser beam output from the edge-emitting chip 40 are constant. More specifically, a controller configured to control the current supplied to the edge-emitting chip 40 is arranged outside the semiconductor light-emitting device 10. The controller is configured to receive a signal corresponding to the second laser beam of the edge-emitting chip 40 that is received by the light-receiving element 38. In an example, a signal of the light-receiving element 38 is output from the second back-surface electrode 62R to the controller. The controller is electrically connected to the second back-surface electrode 62R to receive the signal of the light-receiving element 38. Further, the controller is configured to control the current supplied to the edge-emitting chip 40 in accordance with a difference between a received signal and a set output value, which is a preset light output. In an example, the controller controls the current supplied to the edge-emitting chip 40, so that a received signal has a level that matches the set output value.

### Reflector

As shown in FIG. 3, the semiconductor light-emitting device 10 includes a reflector 70 configured to reflect part of the second laser beam from the edge-emitting chip 40 toward the light-receiving element 38. The reflector 70 is included in the encapsulant 50. The light-receiving surface 38A of the light-receiving element 38 is located at a position that receives at least part of a light reflected by the reflector 70.

The encapsulant 50 includes an inclined surface 57, which serves as the reflector 70. The inclined surface 57 is located at a side of the encapsulant 50 opposite to the first light-emitting surface 43A of the edge-emitting chip 40 with respect to the second light-emitting surface 43B. Accordingly, the inclined surface 57 extends between the first encapsulant side surface 53 and the encapsulant front surface 51. In an example, the inclined surface 57 connects the first encapsulant side surface 53 and the encapsulant front surface 51.

The inclined surface 57 is inclined toward the light-receiving surface 38A of the light-receiving element 38 as the inclined surface 57 extends away from the edge-emitting chip 40 in the X-direction. In other words, the inclined surface 57 is inclined from the encapsulant front surface 51 toward the substrate 20 as the inclined surface 57 extends from the edge-emitting chip 40 toward the first encapsulant side surface 53 in the X-direction.

In plan view, the inclined surface 57 covers the light-receiving surface 38A. In plan view, the inclined surface 57 covers part of the first front surface 41 of the edge-emitting chip 40. More specifically, in plan view, the inclined surface 57 covers one of the two ends of the first front surface 41 of the edge-emitting chip 40 in the X-direction that is located closer to the light-receiving element 38. The inclined surface 57 opposes the second light-emitting surface 43B of the edge-emitting chip 40 in the X-direction.

In plan view, the inclined surface 57 is larger than the second light-emitting surface 43B of the edge-emitting chip 40 in the Y-direction. In plan view, the inclined surface 57 is larger than the light-receiving surface 38A of the light-receiving element 38 in the Y-direction. In an example, the inclined surface 57 is entirely formed between the third encapsulant side surface 55 and the fourth encapsulant side surface 56 in the Y-direction (refer to FIG. 1). Alternatively, the inclined surface 57 may be partially formed between the third encapsulant side surface 55 and the fourth encapsulant side surface 56 in the Y-direction as long as the second laser beam is reflected toward the light-receiving surface 38A.

The light-receiving surface 38A of the light-receiving element 38 is located at a side opposite to the first light-emitting surface 43A of the edge-emitting chip 40 with respect to the second light-emitting surface 43B in the X-direction. The light-receiving surface 38A is located at a position that receives at least part of the second laser beam from the second light-emitting surface 43B that is reflected by the inclined surface 57.

The position of the light-receiving surface 38A in the X-direction and the angle of the inclined surface 57 relative to the encapsulant front surface 51 are set so that the second laser beam from the second light-emitting surface 43B that is reflected by the inclined surface 57 strikes the light-receiving surface 38A.

### Operation

The operation of the semiconductor light-emitting device 10 in accordance with the first embodiment will now be described.

In a semiconductor light-emitting device including an LED chip, it is difficult to increase an output of the light source. Accordingly, instead of the LED chip, an edge-emitting chip, such as an edge-emitting laser (EEL), may be used as the light source as to increase the output.

A semiconductor light-emitting device may include a light-receiving chip that receives part of a light emitted from an LED chip, and the intensity of the light emitted from the LED chip may be controlled in accordance with an amount of the light received by the light-receiving chip.

When this semiconductor light-emitting device includes an edge-emitting chip instead of the LED chip, there is room for improvement in a structure in which the light-receiving chip receives part of a laser beam emitted from the edge-emitting chip.

The first laser beam and the second laser beam output from the edge-emitting chip 40, such as an EEL, may vary in accordance with the temperature of the edge-emitting chip 40. More specifically, the outputs of the first laser beam and the second laser beam from the edge-emitting chip 40 decrease as the temperature of the edge-emitting chip 40 increases. However, in the semiconductor light-emitting device 10, it is desired that at least the output of the first laser beam remains constant regardless of the temperature. The output of the first laser beam emitted from the first light-emitting surface 43A of the edge-emitting chip 40 has a correlation with the output of the second laser beam emitted from the second light-emitting surface 43B. Based on this correlation, the output of the first laser beam can be obtained from the output of the second laser beam.

Accordingly, in the semiconductor light-emitting device 10, the light-receiving element 38 receives part of the second laser beam emitted from the second light-emitting surface 43B of the edge-emitting chip 40, so as to obtain the output of the first laser beam emitted from the edge-emitting chip 40. Then, the APC drive may be executed to set the output of the first laser beam from the edge-emitting chip 40 to a predetermined first laser beam output. That is, the amount of the current supplied to the edge-emitting chip 40 is controlled in accordance with the difference between the output of the second laser beam received by the light-receiving element 38 and the output set value. Consequently, the output of the first laser beam from the edge-emitting chip 40 becomes equal to the predetermined first laser beam output.

In order to perform the APC drive in such a manner, in the semiconductor light-emitting device 10, the encapsulant 50 includes the reflector 70 that reflects part of the second laser beam from the second light-emitting surface 43B of the edge-emitting chip 40 toward the light-receiving element 38. Furthermore, the light-receiving element 38 is located at a position that receives at least part of the light reflected by the reflector 70, such that the light-receiving element 38 readily receives part of the second laser beam from the edge-emitting chip 40. As a result, the current supplied to the edge-emitting chip 40 may be controlled by the APC drive.

### Advantages

The semiconductor light-emitting device 10 of the first embodiment has the following advantages.

(1-1) The semiconductor light-emitting device 10 includes the substrate 20, the light-receiving chip 30, the edge-emitting chip 40, the encapsulant 50, and the reflector 70. The light-receiving chip 30 is arranged on the substrate 20 and includes the light-receiving element 38. The light-receiving element 38 includes the light-receiving surface 38A formed in the chip front surface 31. The edge-emitting chip 40 is bonded to the chip front surface 31 at a position different from the light-receiving surface 38A in plan view. The edge-emitting chip 40 includes the first light-emitting surface 43A and the second light-emitting surface 43B. The first light-emitting surface 43A is configured to emit the first laser beam in the X-direction in plan view. The second light-emitting surface 43B is configured to emit the second laser beam in a direction opposite to the emission direction of the first laser beam. The encapsulant 50 is formed on the substrate 20 by a material that allows passage of the first laser beam and the second laser beam. The encapsulant 50 encapsulates at least part of the edge-emitting chip 40 and at least part of the light-receiving chip 30. The reflector 70 is included in the encapsulant 50 and configured to reflect at least part of the second laser beam toward the light-receiving surface 38A. The light-receiving surface 38A is formed in a position of the chip front surface 31 that receives at least part of a light reflected by the reflector 70.

With this structure, at least part of the second laser beam from the second light-emitting surface 43B of the edge-emitting chip 40 is reflected by the reflector 70 toward the light-receiving surface 38A, and the light-receiving surface 38A is located at a position that receives at least part of the reflected light. Thus, the light-receiving element 38 readily receives at least part of the second laser beam from the edge-emitting chip 40. As a result, when the semiconductor light-emitting device 10 is controlled in accordance with the APC drive, the output of the first laser beam from the first light-emitting surface 43A of the edge-emitting chip 40 may be set to a predetermined value based on the amount of light received by the light-receiving element 38.

In addition, the edge-emitting chip 40 and the light-receiving chip 30 are encapsulated by the encapsulant 50. This avoids collection of foreign matter, such as moisture or dust, on the edge-emitting chip 40 or the light-receiving chip 30. Furthermore, compared with a structure in which the encapsulant 50 is replaced by, for example, light-transmissive side walls arranged on the substrate 20 to surround the edge-emitting chip 40 and the light-receiving chip 30 and a light-transmissive cap covering the opening of the side walls, the manufacturing process is simpler and the costs are lower.

(1-2) The encapsulant 50 includes, as the reflector 70, the inclined surface 57 located at a side opposite to the first light-emitting surface 43A of the edge-emitting chip 40 with respect to the second light-emitting surface 43B. The inclined surface 57 is inclined toward the light-receiving surface 38A of the light-receiving element 38 as the inclined surface 57 extends away from the edge-emitting chip 40 in the X-direction. The light-receiving surface 38A is located at a side opposite to the first light-emitting surface 43A with respect to the second light-emitting surface 43B in the X-direction at a position that receives the second laser beam from the second light-emitting surface 43B that is reflected by the inclined surface 57.

With this structure, the encapsulant 50 includes a part configured to reflect the second laser beam from the second light-emitting surface 43B toward the light-receiving surface 38A. In other words, there is no need for a dedicated component that reflects the second laser beam. This reduces the number of parts of the semiconductor light-emitting device 10, thereby lowering the manufacturing costs of the semiconductor light-emitting device 10.

### Second Embodiment

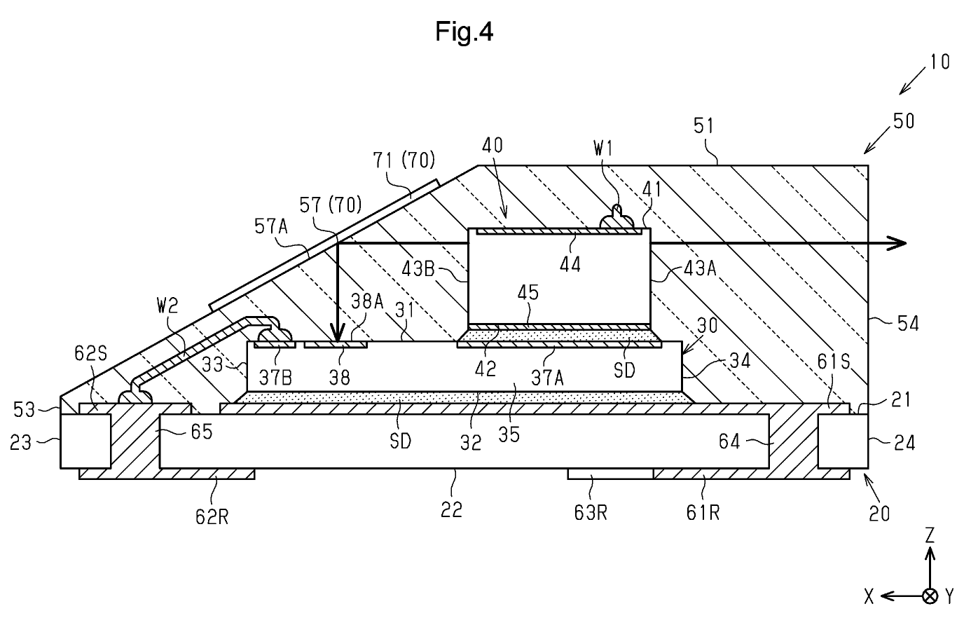

A semiconductor light-emitting device 10 in accordance with a second embodiment will now be described with reference to FIG. 4. The semiconductor light-emitting device 10 of the second embodiment differs from the semiconductor light-emitting device 10 of the first embodiment in the structure of the reflector 70. The description hereafter will focus on the differences from the semiconductor light-emitting device 10 of the first embodiment. Same reference characters are given to those components that are the same as the corresponding components of the semiconductor light-emitting device 10 of the first embodiment, and such components will not be described in detail. FIG. 4 shows a schematic cross-sectional structure of the semiconductor light-emitting device 10 taken along the XZ plane.

As shown in FIG. 4, in the semiconductor light-emitting device 10 of the second embodiment, the reflector 70 includes a reflection layer 71 configured to reflect the second laser beam from the edge-emitting chip 40 toward the light-receiving element 38. The reflection layer 71 is included in the encapsulant 50. More specifically, the reflection layer 71 is disposed on the inclined surface 57. That is, the reflection layer 71 and the encapsulant 50 are different members. The reflection layer 71 may be, for example, a white reflective material. This reflective material may be formed from, for example, a material containing a silicone resin. The reflective material may be a reflective paint. The reflection layer 71 is, for example, formed by applying a reflective material to the inclined surface 57. The reflection layer 71 may be, for example, a metal film of Al or the like. In this case, the reflection layer 71 is formed by depositing a metal film on the inclined surface 57.

The inclined surface 57 includes an opposing region 57A that faces the second light-emitting surface 43B of the edge-emitting chip 40 as viewed in the X-direction. For example, the opposing region 57A is a region of the inclined surface 57 that overlaps the second light-emitting surface 43B as viewed in the X-direction. Accordingly, the opposing region 57A is partially formed between the third encapsulant side surface 55 and the fourth encapsulant side surface 56 (refer to FIG. 1) in the Y-direction. The reflection layer 71 is arranged at least in the opposing region 57A. In other words, the reflection layer 71 is arranged in at least part of the opposing region 57A. In the example shown in FIG. 4, the reflection layer 71 is formed over substantially the entire opposing region 57A. In plan view, the reflection layer 71 covers the light-receiving surface 38A of the light-receiving element 38.

In an example, the reflection layer 71 is rectangular as viewed in a direction orthogonal to the inclined surface 57. In an example, the reflection layer 71 is larger than the light-receiving surface 38A in the Y-direction as viewed in a direction orthogonal to the inclined surface 57. The reflection layer 71 is larger than the second light-emitting surface 43B of the edge-emitting chip 40 in the Y-direction as viewed in a direction orthogonal to the inclined surface 57. In an example, the reflection layer 71 may be entirely formed between the third encapsulant side surface 55 and the fourth encapsulant side surface 56 in the Y-direction. In another example, the reflection layer 71 may be partially formed between the third encapsulant side surface 55 and the fourth encapsulant side surface 56 in the Y-direction.

The shape and size of the reflection layer 71 may be changed. In an example, the reflection layer 71 may be formed in part of the opposing region 57A as long as the reflection layer 71 reflects at least part of the second laser beam from the second light-emitting surface 43B toward the light-receiving surface 38A.

### Advantages

The second embodiment obtains the following advantages.

(2-1) The reflector 70 includes the reflection layer 71 formed on the inclined surface 57 of the encapsulant 50. With this structure, the reflection layer 71 is included in the light-transmissive encapsulant 50, so that the reflection layer 71 readily reflects the second laser beam emitted from the second light-emitting surface 43B of the edge-emitting chip 40. This increases the intensity of the second laser beam reflected by the reflection layer 71, thereby increasing the intensity of the light received by the light-receiving surface 38A of the light-receiving element 38.

The reflection layer 71 is more reflective of the second laser beam than the inclined surface 57 is. This increases the amount of the second laser beam that strikes the light-receiving element 38. In other words, the light-receiving element 38 receives a greater amount of light. The light-receiving element 38 may only receive an amount of light that allows for the APC drive. That is, the light-receiving element 38 may only receive a predetermined amount of light. Accordingly, the output of the second laser beam from the second light-emitting surface 43B may be decreased within a range in which the light-receiving element 38 receives the predetermined amount of light. In this case, the end-face coating of the second light-emitting surface 43B may be adjusted so that the output of the first laser beam from the first light-emitting surface 43A is increased.

### Third Embodiment

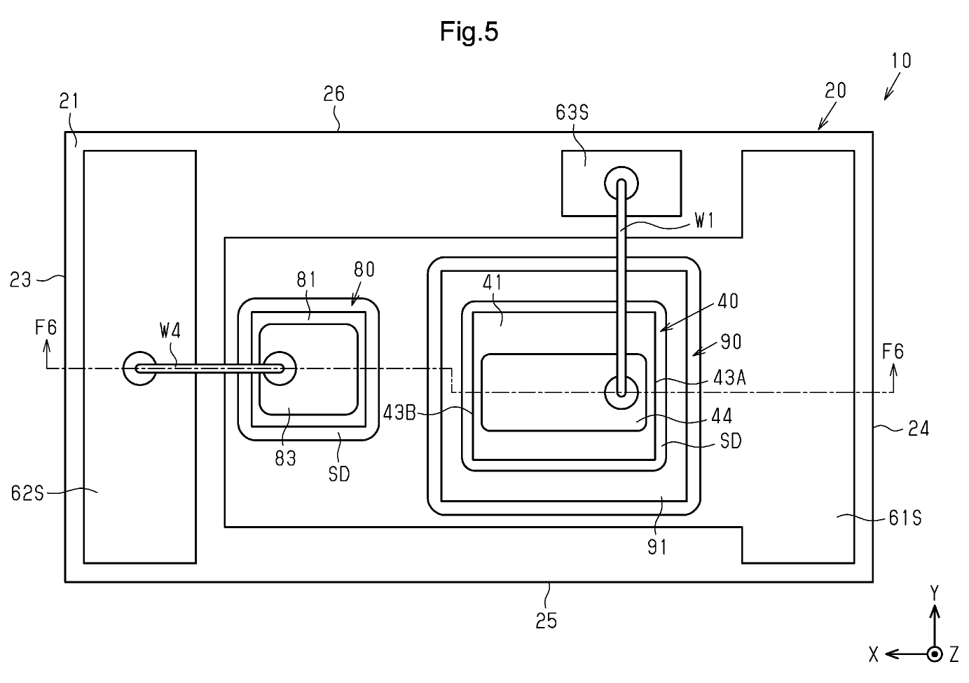

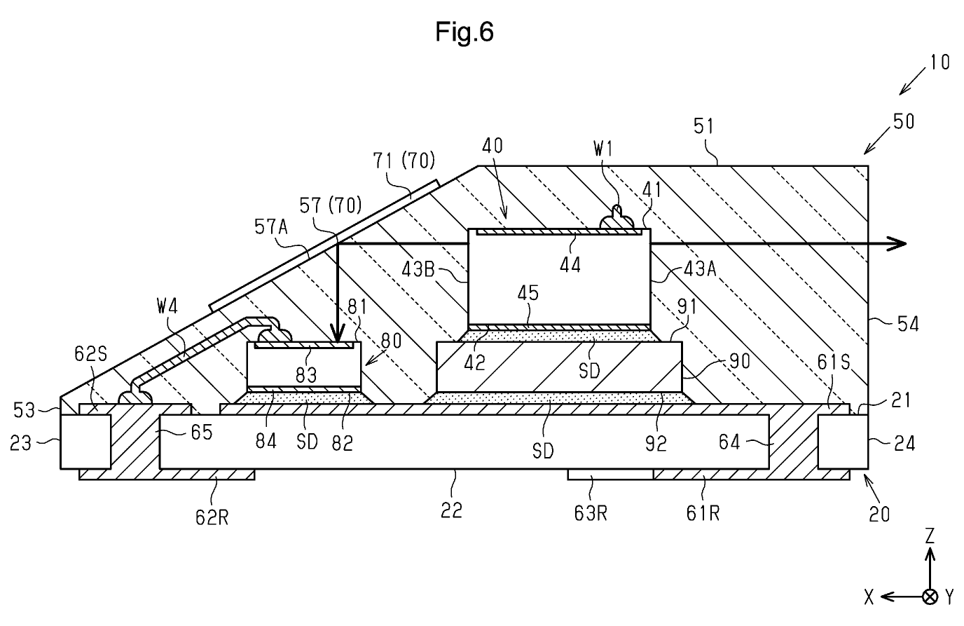

A semiconductor light-emitting device 10 in accordance with a third embodiment will now be described with reference to FIGS. 5 and 6. The semiconductor light-emitting device 10 of the second embodiment mainly differs from the semiconductor light-emitting device 10 of the second embodiment in that a light-receiving chip 80 is included instead of the light-receiving chip 30. The light-receiving chip 80 is smaller than the light-receiving chip 30. The description hereafter will focus on the differences from the semiconductor light-emitting device 10 of the second embodiment. Same reference characters are given to those components that are the same as the corresponding components of the semiconductor light-emitting device 10 of the second embodiment, and such components will not be described in detail. FIG. 5 shows a schematic planar structure of the semiconductor light-emitting device 10 in accordance with the third embodiment in a state in which the encapsulant 50 is omitted. FIG. 6 shows a schematic cross-sectional structure of the semiconductor light-emitting device 10 taken along line F6-F6 shown in FIG. 5.

As shown in FIG. 5, the semiconductor light-emitting device 10 of the third embodiment includes the light-receiving chip 80 arranged on the substrate 20. The light-receiving chip 80 includes, for example, a photodiode. The light-receiving chip 80 is located on the substrate front surface 21 to receive part of the second laser beam from the second light-emitting surface 43B of the edge-emitting chip 40. The light-receiving chip 80 is configured to output a signal corresponding to the amount of second laser beam received.

The light-receiving chip 80 has a shape of a rectangular plate having a thickness-wise direction parallel to the Z-direction. In an example, the light-receiving chip 80 is square in plan view. In the example shown in FIG. 5, the light-receiving chip 80 is smaller than the edge-emitting chip 40 in both the Y-direction and the X-direction. The planar shape and size of the light-receiving chip 80 may be changed.

As shown in FIG. 6, the light-receiving chip 80 includes a second front surface 81 and a second back surface 82 facing opposite directions with respect to the Z-direction. The second front surface 81 faces the same direction as the substrate front surface 21. The second back surface 82 faces the same direction as the substrate back surface 22. The second front surface 81 is an example of the front surface of the light-receiving chip. A second front-surface electrode 83 is formed in the second front surface 81. A second back-surface electrode 84 is formed in the second back surface 82. The second front-surface electrode 83 serves as one of an anode and a cathode of a photodiode included in the light-receiving chip 80. The second back-surface electrode 84 serves as the other one of the anode and the cathode of the photodiode included in the light-receiving chip 80. In the third embodiment, the second front-surface electrode 83 is the anode of the photodiode included in the light-receiving chip 80, and the second back-surface electrode 84 is the cathode of the photodiode included in the light-receiving chip 80. The second front surface 81 includes a light-receiving surface. In the third embodiment, the second front surface 81 is the light-receiving surface. Therefore, the light-receiving chip 80 is configured to generate a voltage signal corresponding to the amount of the second laser light that strikes the second front surface 81.

As shown in FIG. 5, the edge-emitting chip 40 and the light-receiving chip 80 are located next to each other in the X-direction in plan view. In plan view, the light-receiving chip 80 is arranged on the substrate 20 at a position separated from the edge-emitting chip 40 in the X-direction. The edge-emitting chip 40 is located closer to the second substrate side surface 24 than the light-receiving chip 80 is. The light-receiving chip 80 is arranged on the first front-surface electrode 61S at one of the two ends in the X-direction that is located closer to the second front-surface electrode 62S.

The light-receiving chip 80 is bonded to the first front-surface electrode 61S by the conductive bonding material SD. The conductive bonding material SD is in contact with the second back-surface electrode 84 of the light-receiving chip 80. Therefore, the second back-surface electrode 84 is electrically connected to the first front-surface electrode 61S through the conductive bonding material SD.

As shown in FIGS. 5 and 6, the semiconductor light-emitting device 10 includes a sub-mount substrate 90 arranged between the substrate 20 and the edge-emitting chip 40 in the Z-direction. The sub-mount substrate 90 has a shape of a rectangular plate having a thickness-wise direction parallel to the Z-direction. The sub-mount substrate 90 is formed from, for example, a conductive material. The conductive material is, for example, a metal material, such as Cu, Al, or the like. In an example, the sub-mount substrate 90 is formed from Cu.

As shown in FIG. 6, the sub-mount substrate 90 includes a sub-mount front surface 91 and a sub-mount back surface 92 facing opposite directions. The sub-mount front surface 91 faces the same direction as the substrate front surface 21 of the substrate 20. The sub-mount back surface 92 faces the same direction as the substrate back surface 22 of the substrate 20.

The sub-mount substrate 90 is bonded to the first front-surface electrode 61S by the conductive bonding material SD. The conductive bonding material SD is in contact with the sub-mount back surface 92. In the example shown in FIG. 6, the sub-mount substrate 90 has the same thickness as the light-receiving chip 80. In plan view, the sub-mount substrate 90 is larger than the edge-emitting chip 40 in both the X-direction and the Y-direction.

The thickness of the sub-mount substrate 90 may be changed. In an example, the sub-mount substrate 90 may be thicker than the light-receiving chip 80. In another example, the sub-mount substrate 90 may be thinner than the light-receiving chip 80. In this case, at least part of the second light-emitting surface 43B is located closer to the encapsulant front surface 51 than the second front surface 81 (light-receiving surface) of the light-receiving chip 80 is in the Z-direction.

The edge-emitting chip 40 is arranged on the sub-mount substrate 90. The edge-emitting chip 40 is bonded to the sub-mount substrate 90 by the conductive bonding material SD. The conductive bonding material SD is in contact with the sub-mount front surface 91. Therefore, the first back-surface electrode 45 of the edge-emitting chip 40 is electrically connected to the first front-surface electrode 61S through the conductive bonding material SD and the sub-mount substrate 90. Accordingly, the first back-surface electrode 45 is electrically connected to the second back-surface electrode 84 of the light-receiving chip 80.

The sub-mount substrate 90 may be formed from a material containing an insulative material. Examples of the insulative material may include ceramic, a resin material, or the like. The ceramic may be AlN or Al₂O₃. In this case, the sub-mount substrate 90 includes one or more through-wires extending through the sub-mount substrate 90 in the Z-direction. The one or more through-wires electrically connect the first back-surface electrode 45 of the edge-emitting chip 40 and the first front-surface electrode 61S. When ceramic is used as the insulative material of the sub-mount substrate 90, heat of the edge-emitting chip 40 may be readily transferred through the sub-mount substrate 90 to the substrate 20. Therefore, the temperature of the edge-emitting chip 40 will not become excessively high. The sub-mount substrate 90 may be formed by a semiconductor material, such as silicon (Si). Also, in this case the sub-mount substrate 90 includes one or more through-wires extending through the sub-mount substrate 90 in the Z-direction.

In the example shown in FIG. 6, the first back surface 42 of the edge-emitting chip 40 on the sub-mount substrate 90 is located closer to the encapsulant front surface 51 than the second front surface 81 (light-receiving surface) of the light-receiving chip 80 is. Accordingly, the second light-emitting surface 43B of the edge-emitting chip 40 is located closer to the encapsulant front surface 51 than the second front surface 81 (light-receiving surface) of the light-receiving chip 80 is.

A wire W4 is formed on the second front-surface electrode 83 of the light-receiving chip 80. The wire W4 is connected to the second front-surface electrode 62S. Therefore, the second front-surface electrode 83 of the light-receiving chip 80 is electrically connected to the second front-surface electrode 62S through the wire W4. In the example shown in FIG. 5, the wire W4 extends in the X-direction in plan view. The wire W4 is a bonding wire formed by a wire bonder, and is formed from a conductor containing, for example, Au, Al, Cu, or the like. In the same manner as the second embodiment, the first front-surface electrode 44 of the edge-emitting chip 40 is electrically connected to the third front-surface electrode 63S through the wire W1. Unlike the second embodiment, the semiconductor light-emitting device 10 does not include the wire W3.

As shown in FIG. 6, the encapsulant 50 is formed on the substrate 20. The encapsulant 50 encapsulates the light-receiving chip 80, the sub-mount substrate 90, and at least part of the edge-emitting chip 40. In the example shown in FIG. 6, the encapsulant 50 also encapsulates the wires W1 and W4. The encapsulant 50 is an example of a cover. In the third embodiment, the encapsulant 50 encapsulates the entire edge-emitting chip 40.

In the same manner as the second embodiment, the semiconductor light-emitting device 10 includes the reflector 70 configured to reflect at least part of the second laser beam from the second light-emitting surface 43B of the edge-emitting chip 40 toward the light-receiving chip 80. The reflector 70 has the same structure as that of the second embodiment. Specifically, the reflector 70 includes the inclined surface 57 and the reflection layer 71. The light-receiving chip 80 is located at a position that receives at least part of the light reflected by the reflector 70. Specifically, the position of the light-receiving chip 80 in the X-direction and the angle of the inclined surface 57 relative to the encapsulant front surface 51 are set so that the second laser beam from the second light-emitting surface 43B, that is reflected by the inclined surface 57, strikes the second front surface 81 of the light-receiving chip 80.

### Advantages

The semiconductor light-emitting device 10 of the third embodiment has the following advantages.

(3-1) The semiconductor light-emitting device 10 includes the substrate 20, the light-receiving chip 80, the sub-mount substrate 90, the edge-emitting chip 40, the encapsulant 50, and the reflector 70. The light-receiving chip 80 is arranged on the substrate 20 and includes the light-receiving surface formed in the second front surface 81. The sub-mount substrate 90 is arranged on the substrate 20. The edge-emitting chip 40 is arranged on the sub-mount substrate 90 and includes the first light-emitting surface 43A and the second light-emitting surface 43B. The first light-emitting surface 43A is configured to emit the first laser beam in the X-direction in plan view. The second light-emitting surface 43B is configured to emit the second laser beam in a direction opposite to the emission direction of the first laser beam. The encapsulant 50 is formed on the substrate 20 by a material that allows passage of the first laser beam and the second laser beam. The encapsulant 50 encapsulates the light-receiving chip 80, the sub-mount substrate 90, and at least part of the edge-emitting chip 40. The reflector 70 is included in the encapsulant 50 and configured to reflect at least part of the second laser beam toward the light-receiving chip 80. The light-receiving chip 80 is located at a position that receives at least part of the light reflected by the reflector 70.

With this structure, at least part of the second laser beam from the second light-emitting surface 43B of the edge-emitting chip 40 is reflected by the reflector 70 toward the light-receiving chip 80, and the light-receiving chip 80 is located at a position that receives at least part of the reflected light. Thus, the light-receiving chip 80 readily receives at least part of the second laser beam from the edge-emitting chip 40. As a result, when the semiconductor light-emitting device 10 is controlled in accordance with the APC drive, the output of the first laser beam from the first light-emitting surface 43A of the edge-emitting chip 40 may be set to a predetermined value based on the amount of light received by the light-receiving chip 80.

In addition, the edge-emitting chip 40 is arranged on the sub-mount substrate 90, so that heat of the edge-emitting chip 40 is readily transferred through the sub-mount substrate 90 to the substrate 20. Therefore, the temperature of the edge-emitting chip 40 will not become excessively high.

### Fourth Embodiment

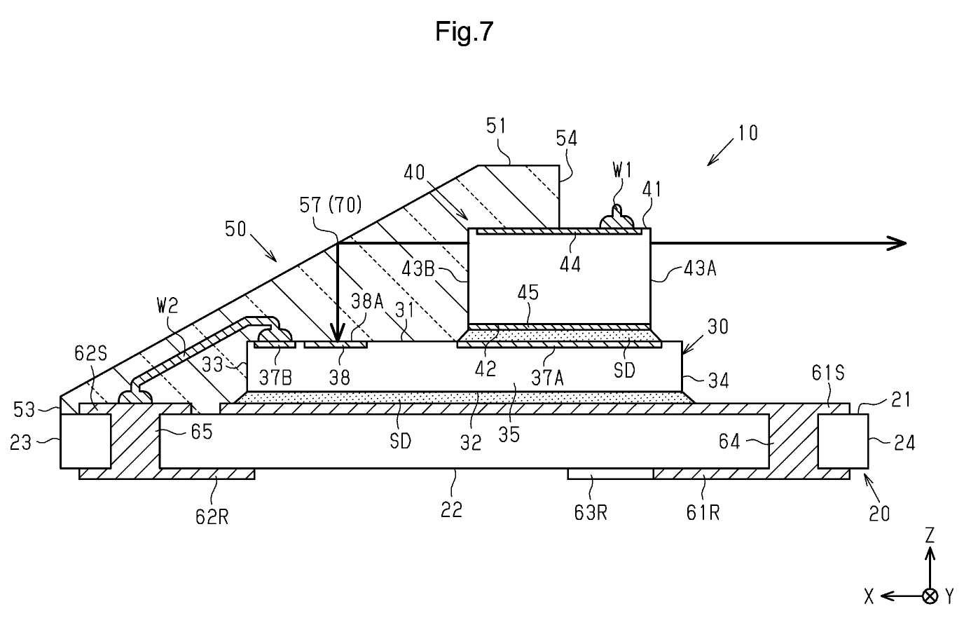

A semiconductor light-emitting device 10 in accordance with a fourth embodiment will now be described with reference to FIG. 7. The semiconductor light-emitting device 10 of the fourth embodiment mainly differs from the semiconductor light-emitting device 10 of the first embodiment in the structure of the encapsulant 50. The description hereafter will focus on the differences from the semiconductor light-emitting device 10 of the first embodiment. Same reference characters are given to those components that are the same as the corresponding components of the semiconductor light-emitting device 10 of the first embodiment, and such components will not be described in detail. FIG. 7 shows a schematic cross-sectional structure of the semiconductor light-emitting device 10 taken along the XZ plane.

As shown in FIG. 7, the encapsulant 50 of the fourth embodiment encapsulates the second light-emitting surface 43B of the edge-emitting chip 40 and exposes the first light-emitting surface 43A. The second encapsulant side surface 54 of the encapsulant 50 is located closer to the first substrate side surface 23 of the substrate 20 than the second substrate side surface 24 is. The second encapsulant side surface 54 is located closer to the first substrate side surface 23 than the first light-emitting surface 43A of the edge-emitting chip 40 is. Accordingly, the first light-emitting surface 43A is exposed from the encapsulant 50. The second encapsulant side surface 54 is located closer to the second substrate side surface 24 than the second light-emitting surface 43B of the edge-emitting chip 40 is. Accordingly, the second light-emitting surface 43B is encapsulated by the encapsulant 50. Further, the light-receiving surface 38A of the light-receiving element 38 is encapsulated by the encapsulant 50. Thus, the encapsulant 50 encapsulates at least the second light-emitting surface 43B of the edge-emitting chip 40 and the light-receiving surface 38A of the light-receiving chip 30.

In the example shown in FIG. 7, the wire W1 is exposed from the encapsulant 50. Therefore, the third front-surface electrode 63S (refer to FIG. 2) and part of the first front-surface electrode 44 of the edge-emitting chip 40 are exposed from the encapsulant 50. That is, the wire W1 electrically connects the first front-surface electrode 44 and the third front-surface electrode 63S outside the encapsulant 50.

Part of the light-receiving chip 30 and part of the first front-surface electrode 61S are exposed from the encapsulant 50. Although not shown in FIG. 7, the third electrode 37C (refer to FIG. 2) of the light-receiving chip 30 is exposed from the encapsulant 50. Also, the wire W3 (refer to FIG. 2) is exposed from the encapsulant 50. Thus, the wire W3 electrically connects the third electrode 37C and the first front-surface electrode 61S outside the encapsulant 50.

In the same manner as the first embodiment, the encapsulant 50 includes the inclined surface 57, which serves as the reflector 70. Therefore, at least part of the second laser beam from the second light-emitting surface 43B of the edge-emitting chip 40 is reflected by the inclined surface 57 and strikes the light-receiving surface 38A. On the other hand, the first laser beam from the first light-emitting surface 43A of the edge-emitting chip 40 is emitted out of the semiconductor light-emitting device 10 without passing through the encapsulant 50.

### Advantages

The semiconductor light-emitting device 10 of the fourth embodiment has the following advantages.

(4-1) The encapsulant 50 encapsulates the second light-emitting surface 43B of the edge-emitting chip 40 and exposes the first light-emitting surface 43A.

With this structure, the first laser beam from the first light-emitting surface 43A is emitted out of the semiconductor light-emitting device 10 without passing through the encapsulant 50. This avoids the first laser beam from being diffused by the encapsulant 50. In contrast, the encapsulant 50 encapsulates the second light-emitting surface 43B and the light-receiving surface 38A of the light-receiving element 38, so that the second laser beam from the second light-emitting surface 43B is reflected by the reflector 70 and strikes the light-receiving surface 38A. As a result, when the semiconductor light-emitting device 10 is controlled in accordance with the APC drive, the output of the first laser beam from the first light-emitting surface 43A of the edge-emitting chip 40 may be set to a predetermined value based on the amount of light received by the light-receiving element 38.

### Fifth Embodiment

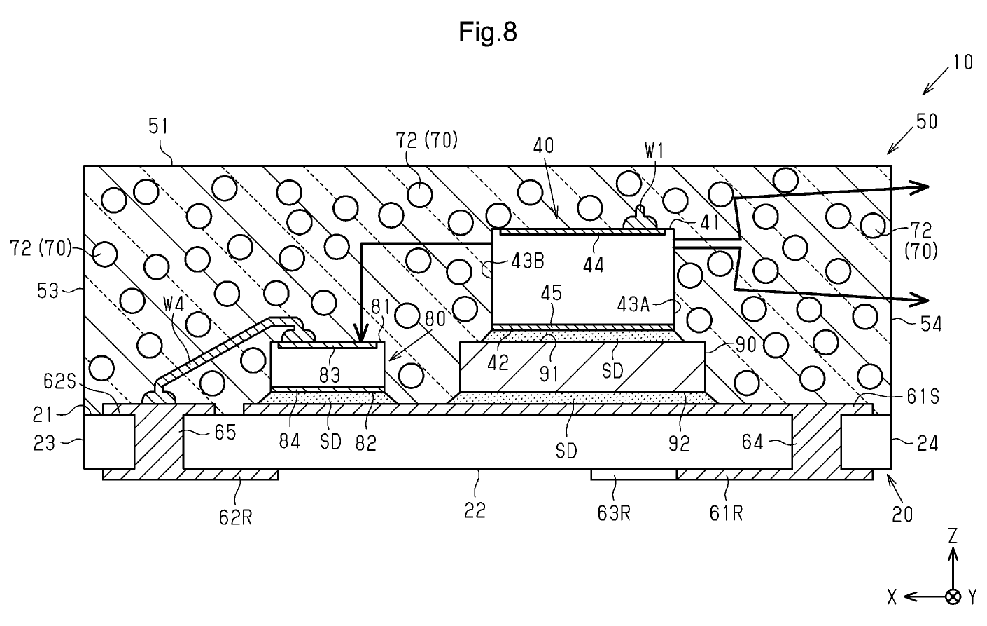

A semiconductor light-emitting device 10 in accordance with a fifth embodiment will now be described with reference to FIG. 8. The semiconductor light-emitting device 10 of the fifth embodiment mainly differs from the semiconductor light-emitting device 10 of the third embodiment in the structure of the encapsulant 50 and the structure of the reflector 70. The description hereafter will focus on the differences from the semiconductor light-emitting device 10 of the third embodiment. Same reference characters are given to those components that are the same as the corresponding components of the semiconductor light-emitting device 10 of the third embodiment, and such components will not be described in detail. FIG. 8 shows a schematic cross-sectional structure of the semiconductor light-emitting device 10 taken along the XZ plane.

As shown in FIG. 8, in the fifth embodiment, the inclined surface 57 (refer to FIG. 6) is omitted from the encapsulant 50. Also, the reflection layer 71 (refer to FIG. 6) is omitted from the reflector 70. The encapsulant 50 has a shape of a rectangular plate having a thickness-wise direction parallel to the Z-direction.

The encapsulant 50 includes, as the reflector 70, diffusers 72 configured to diffuse light. The diffusers 72 diffuse light inside the encapsulant 50 by reflecting (scattering) the light at interfaces of the diffusers 72 and the resin in the encapsulant 50. In this manner, the light-receiving chip 80 receives part of the second laser beam, which is emitted from the second light-emitting surface 43B of the edge-emitting chip 40 and is diffused by the diffusers 72 inside the encapsulant 50. In addition, the diffusers 72 diffuse the first laser beam, which is emitted from the first light-emitting surface 43A of the edge-emitting chip 40, inside the encapsulant 50. This increases the directivity angle of the first laser beam emitted out of the encapsulant 50.

Although not particularly limited, the material of the diffusers 72 may be, for example, silica or other types of glass material. In an example, the diffusers 72 are spherical silica fillers. Although not particularly limited, the particle diameter of the diffusers 72 may be, for example, sufficiently small with respect to the wavelength of the laser beam emitted from the edge-emitting chip 40, so that diffusion occurs dominantly.

The diffusers 72 are dispersed in the encapsulant 50 as fine particles. The diffusers 72 are mixed with the encapsulant 50 at a predetermined compound ratio. In an example, the diffusers 72 are evenly dispersed in the encapsulant 50. The compound ratio of the diffusers 72 to the encapsulant 50 is not particularly limited, and may be set to any value greater than 0% and less than 100%. As the compound ratio of the diffusers 72 is increased, the light-receiving chip 80 receives the scattered light more easily, and the directivity angle of the first laser beam from the edge-emitting chip 40 becomes wider. Further, when the compound ratio of the diffusers 72 has an upper limit set to a predetermined value, the amount and intensity of the laser beam (first laser beam) emitted out of the semiconductor light-emitting device 10 will not become excessively low.

In an example, the diffusers 72 may have a smaller thermal expansion coefficient than the resin of the encapsulant 50. In this structure, the diffusers 72 may reduce thermal stress generated in the encapsulant 50, compared with a structure in which the encapsulant 50 is formed by only resin. This restricts breakage of the wires W1 or W4 caused by thermal stress of the encapsulant 50.

### Advantages

The semiconductor light-emitting device 10 of the fifth embodiment has the following advantages.

(5-1) The reflector 70 includes the diffusers 72 arranged inside the encapsulant 50 and configured to diffuse the first laser beam and the second laser beam from the edge-emitting chip 40. With this structure, the diffusers 72 diffuse the second laser beam from the second light-emitting surface 43B of the edge-emitting chip 40, so that part of the second laser beam is diffused toward the light-receiving chip 80. As a result, the light-receiving chip 80 readily receives part of the second laser beam from the edge-emitting chip 40.

In addition, the diffusers 72 diffuse the first laser beam from the first light-emitting surface 43A of the edge-emitting chip 40, so that the directivity angle of the first laser beam may be increased. As a result, the directivity angle of the laser beam from the semiconductor light-emitting device 10 is increased.

### Sixth Embodiment

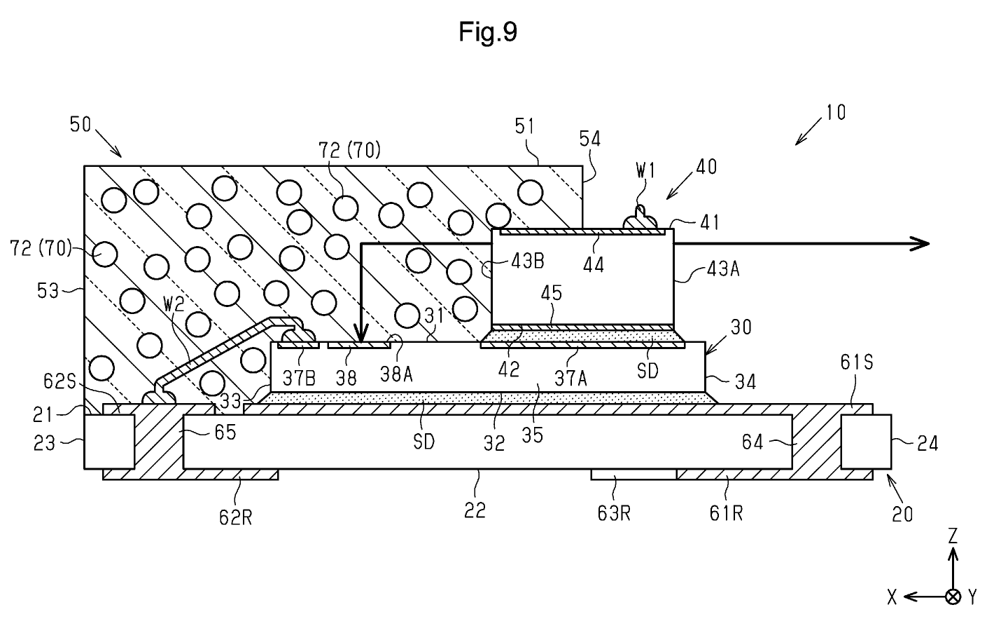

A semiconductor light-emitting device 10 in accordance with a sixth embodiment will now be described with reference to FIG. 9. The semiconductor light-emitting device 10 of the sixth embodiment mainly differs from the semiconductor light-emitting device 10 of the fifth embodiment in the structure of the encapsulant 50. Further, the semiconductor light-emitting device 10 of the sixth embodiment differs from the semiconductor light-emitting device 10 of the fifth embodiment in that the light-receiving chip 30 of the first embodiment is arranged instead of the light-receiving chip 80. The description hereafter will focus on the differences from the semiconductor light-emitting device 10 of the first and fifth embodiments. Same reference characters are given to those components that are the same as the corresponding components of the semiconductor light-emitting device 10 of the first and fifth embodiments, and such components will not be described in detail. FIG. 9 shows a schematic cross-sectional structure of the semiconductor light-emitting device 10 taken along the XZ plane.

As shown in FIG. 9, the encapsulant 50 of the sixth embodiment encapsulates the second light-emitting surface 43B of the edge-emitting chip 40 and exposes the first light-emitting surface 43A. The second encapsulant side surface 54 of the encapsulant 50 is located closer to the first substrate side surface 23 of the substrate 20 than the second substrate side surface 24 is. The second encapsulant side surface 54 is located closer to the first substrate side surface 23 than the first light-emitting surface 43A of the edge-emitting chip 40 is. Accordingly, the first light-emitting surface 43A is exposed from the encapsulant 50. The second encapsulant side surface 54 is located closer to the second substrate side surface 24 than the second light-emitting surface 43B of the edge-emitting chip 40 is. Accordingly, the second light-emitting surface 43B is encapsulated by the encapsulant 50. Further, the light-receiving surface 38A of the light-receiving element 38 is encapsulated by the encapsulant 50. Thus, the encapsulant 50 encapsulates at least the second light-emitting surface 43B of the edge-emitting chip 40 and the light-receiving surface 38A of the light-receiving chip 30.

In the example shown in FIG. 9, the wire W1 is exposed from the encapsulant 50. Also, the third front-surface electrode 63S (refer to FIG. 2) and part of the first front-surface electrode 44 of the edge-emitting chip 40 are exposed from the encapsulant 50. Thus, the wire W1 electrically connects the first front-surface electrode 44 and the third front-surface electrode 63S outside the encapsulant 50.

Part of the light-receiving chip 30 and part of the first front-surface electrode 61S are exposed from the encapsulant 50. Although not shown in FIG. 9, the third electrode 37C (refer to FIG. 2) of the light-receiving chip 30 is exposed from the encapsulant 50. Also, the wire W3 (refer to FIG. 2) is exposed from the encapsulant 50. Thus, the wire W3 electrically connects the third electrode 37C and the first front-surface electrode 61S outside the encapsulant 50.

In the same manner as the fifth embodiment, the encapsulant 50 includes the diffusers 72, which serve as the reflector 70. Therefore, at least part of the second laser beam from the second light-emitting surface 43B of the edge-emitting chip 40 is scattered by the diffusers 72 and strikes the light-receiving surface 38A. The first laser beam from the first light-emitting surface 43A of the edge-emitting chip 40 is emitted out of the semiconductor light-emitting device 10 without passing through the encapsulant 50. Therefore, the first laser beam is emitted out of the semiconductor light-emitting device 10 without being scattered by the diffusers 72, and the directivity angle of the first laser beam remains relatively small.

### Advantages

The semiconductor light-emitting device 10 of the sixth embodiment has the following advantages.

(6-1) The encapsulant 50 encapsulates the second light-emitting surface 43B of the edge-emitting chip 40 and exposes the first light-emitting surface 43A.

With this structure, the first laser beam from the first light-emitting surface 43A is emitted out of the semiconductor light-emitting device 10 without passing through the encapsulant 50. This avoids the first laser beam from being diffused by the diffusers 72 of the encapsulant 50. In contrast, the encapsulant 50 encapsulates the second light-emitting surface 43B and the light-receiving surface 38A of the light-receiving element 38, so that the second laser beam from the second light-emitting surface 43B is diffused by the diffusers 72 and strikes the light-receiving surface 38A. As a result, when the semiconductor light-emitting device 10 is controlled in accordance with the APC drive, the output of the first laser beam from the first light-emitting surface 43A of the edge-emitting chip 40 may be set to a predetermined value based on the amount of light received by the light-receiving element 38.

### Seventh Embodiment

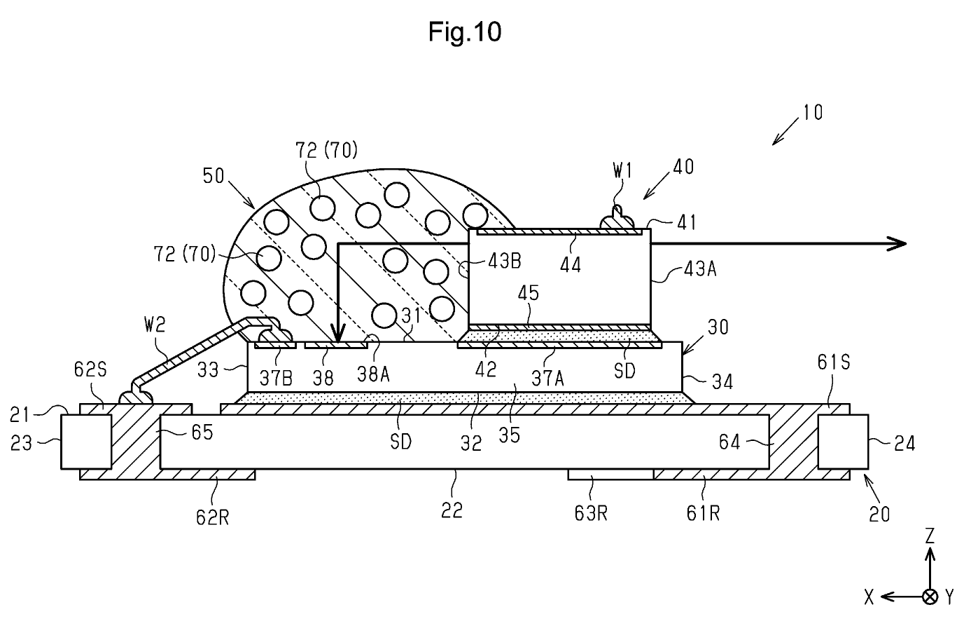

A semiconductor light-emitting device 10 in accordance with a seventh embodiment will now be described with reference to FIG. 10. The semiconductor light-emitting device 10 of the seventh embodiment mainly differs from the semiconductor light-emitting device 10 of the sixth embodiment in the structure of the encapsulant 50. The description hereafter will focus on the differences from the semiconductor light-emitting device 10 of the sixth embodiment. Same reference characters are given to those components that are the same as the corresponding components of the semiconductor light-emitting device 10 of the sixth embodiment, and such components will not be described in detail. FIG. 10 shows a schematic cross-sectional structure of the semiconductor light-emitting device 10 taken along the XZ plane.

As shown in FIG. 10, in the semiconductor light-emitting device 10 of the seventh embodiment, the encapsulant 50 is arranged on the light-receiving chip 30. In other words, the encapsulant 50 is not in contact with the substrate 20.

The encapsulant 50 is located between the second light-emitting surface 43B of the edge-emitting chip 40 and one of the two ends of the light-receiving chip 30 in the X-direction that is located closer to the first substrate side surface 23. The encapsulant 50 encapsulates both the second light-emitting surface 43B and the light-receiving surface 38A. The encapsulant 50 covers part of the first front surface 41 of the edge-emitting chip 40. More specifically, the encapsulant 50 covers one of the two ends of the first front surface 41 in the X-direction that is located closer to the second light-emitting surface 43B. The encapsulant 50 is, for example, formed by potting. Accordingly, the encapsulant front surface 51 of the encapsulant 50 is substantially spherical.

In the same manner as the sixth embodiment, the encapsulant 50 includes the diffusers 72, which serve as the reflector 70. Therefore, at least part of the second laser beam from the second light-emitting surface 43B of the edge-emitting chip 40 is scattered by the diffusers 72 and strikes the light-receiving surface 38A. The first laser beam from the first light-emitting surface 43A of the edge-emitting chip 40 is emitted out of the semiconductor light-emitting device 10 without passing through the encapsulant 50. Therefore, the first laser beam is emitted out of the semiconductor light-emitting device 10 without being scattered by the diffusers 72, and the directivity angle of the first laser beam remains relatively small.

### Advantages

The semiconductor light-emitting device 10 of the seventh embodiment has the following advantages.

(7-1) The encapsulant 50 is arranged on the light-receiving chip 30, so as to encapsulate the second light-emitting surface 43B of the edge-emitting chip 40 and the light-receiving surface 38A of the light-receiving element 38 and expose the first light-emitting surface 43A. The reflector 70 includes the diffusers 72 arranged inside the encapsulant 50 and configured to diffuse the second laser beam from the second light-emitting surface 43B.

With this structure, the first laser beam from the first light-emitting surface 43A is emitted out of the semiconductor light-emitting device 10 without passing through the encapsulant 50. This avoids the first laser beam from being diffused by the diffusers 72 of the encapsulant 50. In contrast, the encapsulant 50 encapsulates the second light-emitting surface 43B and the light-receiving surface 38A of the light-receiving element 38, so that the second laser beam from the second light-emitting surface 43B is diffused by the diffusers 72 and strikes the light-receiving surface 38A. As a result, when the semiconductor light-emitting device 10 is controlled in accordance with the APC drive, the output of the first laser beam from the first light-emitting surface 43A of the edge-emitting chip 40 may be set to a predetermined value based on the amount of light received by the light-receiving element 38.

In addition, the encapsulant 50 is arranged on the light-receiving chip 30 to encapsulate the light-receiving surface 38A and the second light-emitting surface 43B. This reduces the volume of the encapsulant 50, thereby lowering the manufacturing costs of the semiconductor light-emitting device 10.

### Eighth Embodiment

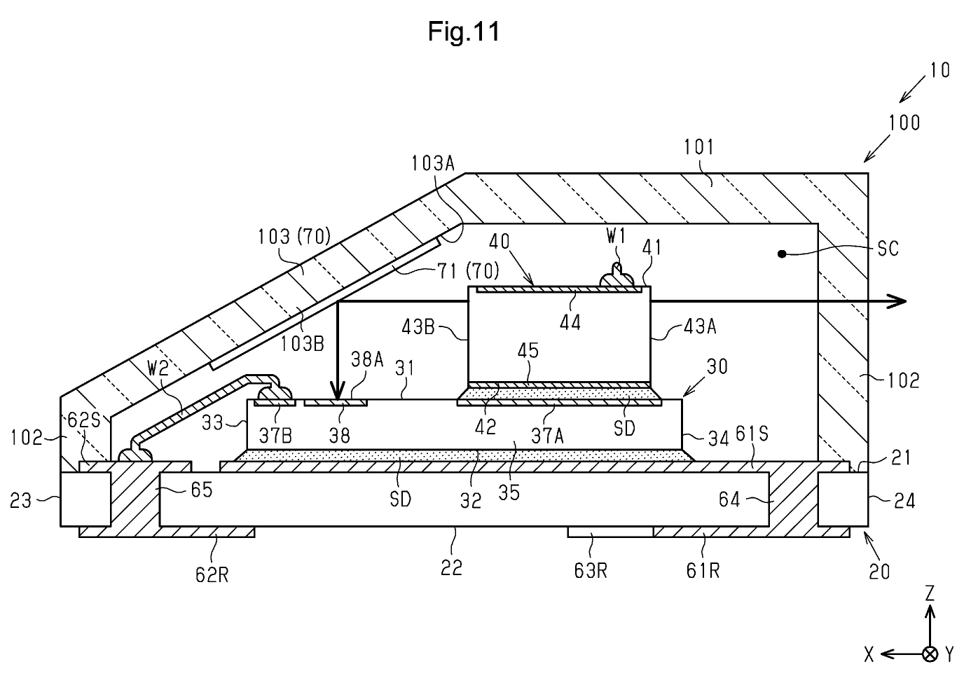

A semiconductor light-emitting device 10 in accordance with an eighth embodiment will now be described with reference to FIG. 11. The semiconductor light-emitting device 10 of the eighth embodiment mainly differs from the semiconductor light-emitting device 10 of the first embodiment in the structure of the encapsulant 50. The description hereafter will focus on the differences from the semiconductor light-emitting device 10 of the first embodiment. Same reference characters are given to those components that are the same as the corresponding components of the semiconductor light-emitting device 10 of the first embodiment, and such components will not be described in detail. FIG. 11 shows a schematic cross-sectional structure of the semiconductor light-emitting device 10 taken along the XZ plane.

As shown in FIG. 11, the semiconductor light-emitting device 10 of the eighth embodiment includes a case 100, which serves as a cover, instead of the encapsulant 50 (refer to FIG. 1). The case 100 accommodates at least part of the edge-emitting chip 40 and at least part of the light-receiving chip 30. In the example shown in FIG. 11, the case 100 accommodates the entire edge-emitting chip 40 and the entire light-receiving chip 30. More specifically, the case 100 is arranged on the substrate 20. The case 100 is attached to the substrate 20 by, for example, an adhesive. The case 100 and the substrate front surface 21 of the substrate 20 define a sealed compartment SC. The edge-emitting chip 40 and the light-receiving chip 30 are disposed in the sealed compartment SC.

The case 100 has a shape of a box that is open toward the substrate 20. The case 100 includes an upper wall 101 and four side walls 102. The upper wall 101 has a shape of a flat plate orthogonal to the Z-direction. In plan view, the four side walls 102 extend along the first to fourth substrate side surfaces 23 to 26 (refer to FIG. 1).

The case 100 is formed by a material that allows passage of the first laser beam and the second laser beam from the edge-emitting chip 40. The encapsulant 50 is formed from, for example, a material containing at least one of a silicone resin, an epoxy resin, and an acrylic resin. In an example, the case 100 is formed from a silicone resin.

The case 100 includes the reflector 70 configured to reflect at least part of the second laser beam from the edge-emitting chip 40 toward the light-receiving surface 38A of the light-receiving element 38. The case 100 includes, as the reflector 70, an inclined part 103 located at a side opposite to the first light-emitting surface 43A of the edge-emitting chip 40 with respect to the second light-emitting surface 43B. The inclined part 103 is inclined toward the light-receiving element 38 as the inclined part 103 extends away from the edge-emitting chip 40 in the X-direction. The inclined part 103 is arranged between the upper wall 101 and one of the four side walls 102 that extends along the first substrate side surface 23.

The reflector 70 includes the reflection layer 71 formed on the inclined part 103. The reflection layer 71 is formed on an inner surface 103A of the inclined part 103. The reflection layer 71 is configured to reflect the second laser beam from the edge-emitting chip 40 toward the light-receiving surface 38A of the light-receiving element 38. The reflection layer 71 and the case 100 are different members. The reflection layer 71 may be, for example, a white reflective material. This reflective material may be formed from, for example, a material containing a silicone resin. The reflective material may be a reflective paint. The reflection layer 71 is, for example, formed by applying a reflective material to the inner surface 103A of the inclined part 103. The reflection layer 71 may be, for example, a metal film of Al or the like. In this case, the reflection layer 71 is formed by depositing a metal film on the inner surface 103A of the inclined part 103.

The inclined part 103 includes an opposing region 103B that faces the second light-emitting surface 43B of the edge-emitting chip 40 as viewed in the X-direction. For example, the opposing region 103B is a region of the inclined part 103 that overlaps the second light-emitting surface 43B as viewed in the X-direction. Accordingly, the opposing region 103B is partially formed between the two side walls 102 that form two ends of the case 100 in the Y-direction. The reflection layer 71 is arranged at least in the opposing region 103B. In other words, the reflection layer 71 is arranged in at least part of the opposing region 103B. In the example shown in FIG. 11, the reflection layer 71 is formed over substantially the entire opposing region 103B. In plan view, the reflection layer 71 covers the light-receiving surface 38A of the light-receiving element 38.

In an example, the reflection layer 71 is rectangular as viewed in a direction orthogonal to the inner surface 103A of the inclined part 103. In an example, the reflection layer 71 is larger than the light-receiving surface 38A in the Y-direction as viewed in a direction orthogonal to the inner surface 103A of the inclined part 103. The reflection layer 71 is larger than the second light-emitting surface 43B of the edge-emitting chip 40 in a direction orthogonal to the inner surface 103A of the inclined part 103. In an example, the reflection layer 71 may be entirely formed between the two side walls 102 that form two ends of the case 100 in the Y-direction. In another example, the reflection layer 71 may be partially formed between the two side walls 102 that form two ends of the case 100 in the Y-direction.

The shape and size of the reflection layer 71 may be changed. In an example, the reflection layer 71 may be formed in part of the opposing region 103B as long as the reflection layer 71 reflects at least part of the second laser beam from the second light-emitting surface 43B toward the light-receiving surface 38A.

### Advantages

The semiconductor light-emitting device 10 of the eighth embodiment has the following advantages.

(8-1) In a structure of the semiconductor light-emitting device 10 in which the encapsulant 50 encapsulates the wires W1 to W3 (refer to FIG. 2), when there is a temperature change, a stress may be applied to the wires W1 to W3 due to a difference in thermal expansion coefficient between the encapsulant 50 and the wires W1 to W3. In this respect, the semiconductor light-emitting device 10 of the eighth embodiment includes the case 100 that accommodates at least part of the edge-emitting chip 40 and at least part of the light-receiving chip 30. With this structure, the wires W1 to W3 are disposed in the sealed compartment SC, which is defined by the case 100 and the substrate 20. Therefore, a stress will not be applied to the wires W1 to W3 due to a temperature change.

(8-2) The reflector 70 includes the reflection layer 71 formed on the inner surface 103A of the inclined part 103 of the case 100.

With this structure, the reflection layer 71 is included in the light-transmissive case 100, so that the reflection layer 71 readily reflects the second laser beam emitted from the second light-emitting surface 43B of the edge-emitting chip 40. This increases the intensity of the second laser beam reflected by the reflection layer 71, thereby increasing the intensity of the light received by the light-receiving surface 38A of the light-receiving element 38.

The reflection layer 71 is more reflective of the second laser beam than the inclined part 103 is. This increases the amount of the second laser beam that strikes the light-receiving element 38. In other words, the light-receiving element 38 receives a greater amount of light. The light-receiving element 38 may only receive an amount of light that allows for the APC drive. That is, the light-receiving element 38 may only receive a predetermined amount of light. Accordingly, the output of the second laser beam from the second light-emitting surface 43B may be decreased within a range in which the light-receiving element 38 receives the predetermined amount of light. In this case, the end-face coating of the second light-emitting surface 43B may be adjusted so that the output of the first laser beam from the first light-emitting surface 43A is increased.

### Ninth Embodiment

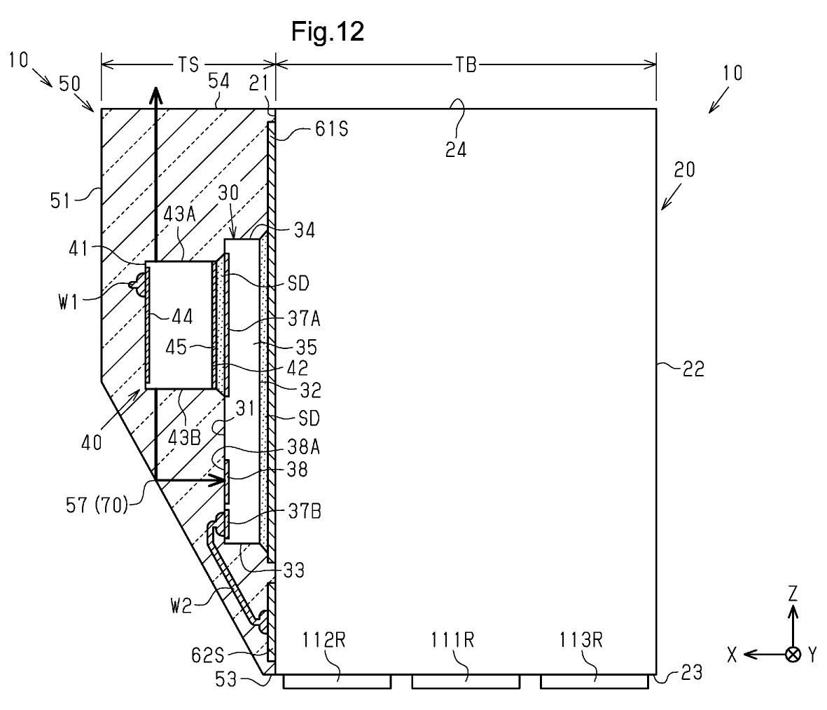

A semiconductor light-emitting device 10 in accordance with a ninth embodiment will now be described with reference to FIG. 12. The semiconductor light-emitting device 10 of the ninth embodiment mainly differs from the semiconductor light-emitting device 10 of the first embodiment in the structure of the substrate 20. The description hereafter will focus on the differences from the semiconductor light-emitting device 10 of the first embodiment. Same reference characters are given to those components that are the same as the corresponding components of the semiconductor light-emitting device 10 of the first embodiment, and such components will not be described in detail. FIG. 12 shows a schematic cross-sectional structure of the semiconductor light-emitting device 10 taken along the XZ plane.

As shown in FIG. 12, in the semiconductor light-emitting device 10 of the ninth embodiment, the substrate 20 has a thickness TB that is greater than a thickness TB of the substrate 20 of the first embodiment (refer to FIG. 3). In an example, the thickness TB of the substrate 20 is greater than a thickness TS of the encapsulant 50. In the semiconductor light-emitting device 10 of the ninth embodiment, the first substrate side surface 23 may serve as a mounting surface. Specifically, a first external terminal 111R, a second external terminal 112R, and a third external terminal 113R are formed on the first substrate side surface 23. For example, when mounting the semiconductor light-emitting device 10 to a circuit board, the first to third external terminals 111R to 113R are bonded to the circuit board by a conductive bonding material. The first to third external terminals 111R to 113R are an example of an external terminal of the substrate. In the ninth embodiment, the X-direction is the thickness-wise direction of the substrate.

The first front-surface electrode 61S is electrically connected to the first external terminal 111R inside the substrate 20. The second front-surface electrode 62S is electrically connected to the second external terminal 112R inside the substrate 20. The third front-surface electrode 63S (not shown in FIG. 12, refer to FIG. 2) is electrically connected to the third external terminal 113R inside the substrate 20. In other words, the substrate 20 includes a first connector that electrically connects the first front-surface electrode 61S to the first external terminal 111R, a second connector that electrically connects the second front-surface electrode 62S to the second external terminal 112R, and a third connector that electrically connects the third front-surface electrode 63S to the third external terminal 113R. The first to third connectors each include, for example, a wiring layer formed from a metal coating, and a via electrically connected to the wiring layer.

In the edge-emitting chip 40, the first light-emitting surface 43A and the second light-emitting surface 43B face opposite directions with respect to the Z-direction. Therefore, the edge-emitting chip 40 is configured to emit the first laser beam from the first light-emitting surface 43A in the Z-direction that intersects the thickness-wise direction of the substrate 20 (X-direction). The edge-emitting chip 40 is configured to emit the second laser beam from the second light-emitting surface 43B in a direction opposite to the first laser beam with respect to the Z-direction. The semiconductor light-emitting device 10 of the ninth embodiment has the same advantages as the first embodiment.

### Modified Examples

The above embodiments may be modified as described below. The above embodiments and the modified examples described below can be combined as long as there is no technical contradiction.

The first to ninth embodiments may be combined as long as the combined modifications remain technically consistent with each other.

In an example, in the first to fourth and ninth embodiments, the encapsulant 50 may include the diffusers 72 of the fifth embodiment.

In an example, in the fourth embodiment, the reflector 70 may include the reflection layer 71 of the second embodiment.

In an example, in the fourth embodiment, the semiconductor light-emitting device 10 may include the light-receiving chip 80 and the sub-mount substrate 90 of the third embodiment, instead of the light-receiving chip 30.

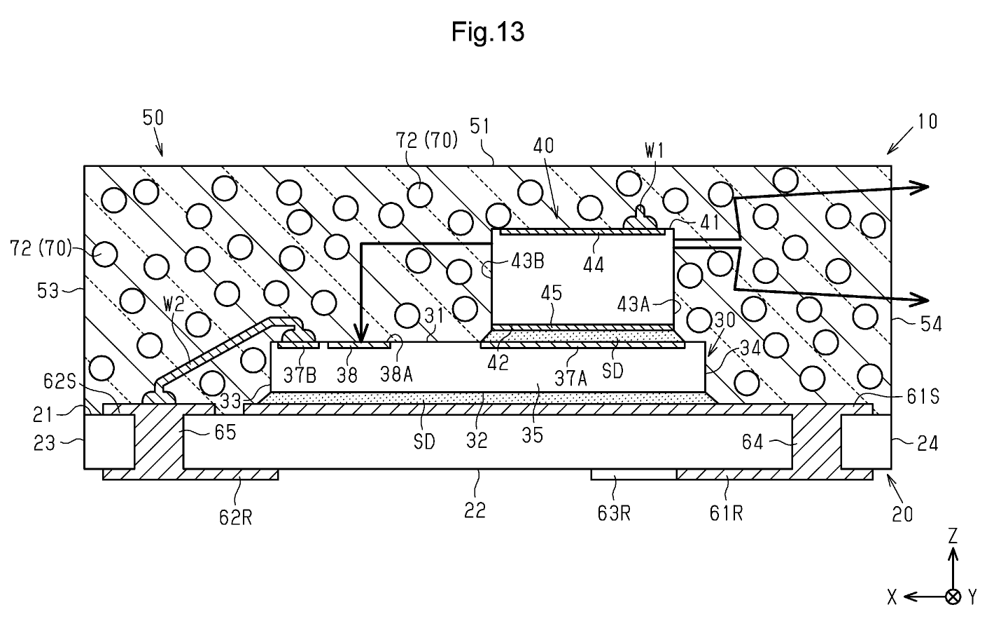

In an example, in the fifth embodiment, as shown in FIG. 13, the semiconductor light-emitting device 10 may include the light-receiving chip 30 of the first embodiment, instead of the light-receiving chip 80 and the sub-mount substrate 90.

In an example, in the sixth embodiment, the semiconductor light-emitting device 10 may include the light-receiving chip 80 and the sub-mount substrate 90 of the third embodiment, instead of the light-receiving chip 30.

In an example, in the eighth embodiment, the semiconductor light-emitting device 10 may include the light-receiving chip 80 and the sub-mount substrate 90 of the third embodiment, instead of the light-receiving chip 30.

In an example, in the third and eighth embodiments, the reflection layer 71 may be omitted from the reflector 70.

In an example, in the ninth embodiment, the semiconductor light-emitting device 10 may include the case 100, instead of the encapsulant 50.

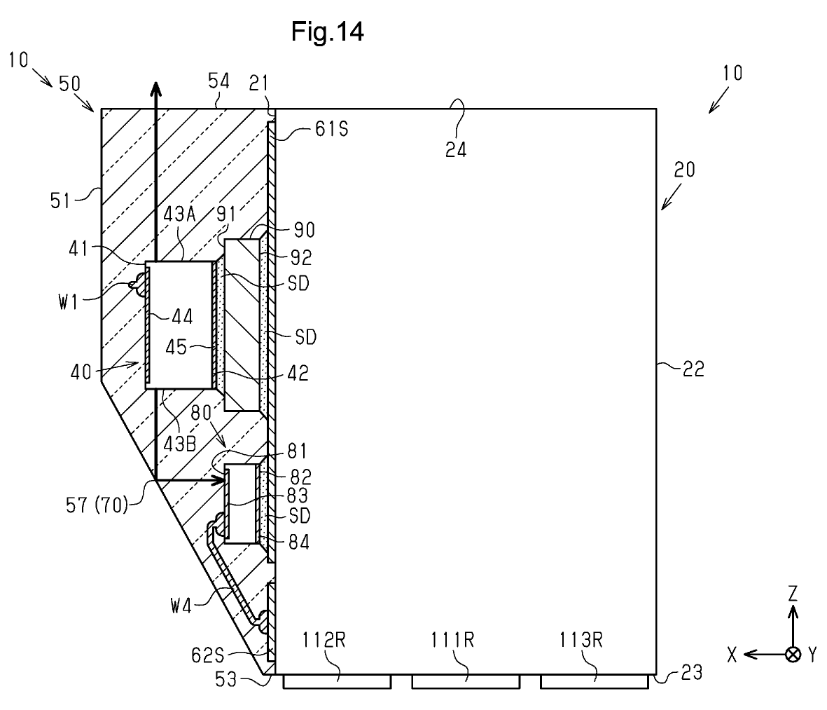

In an example, in the ninth embodiment, as shown in FIG. 14, the semiconductor light-emitting device 10 may include the light-receiving chip 80 and the sub-mount substrate 90 of the third embodiment, instead of the light-receiving chip 30.

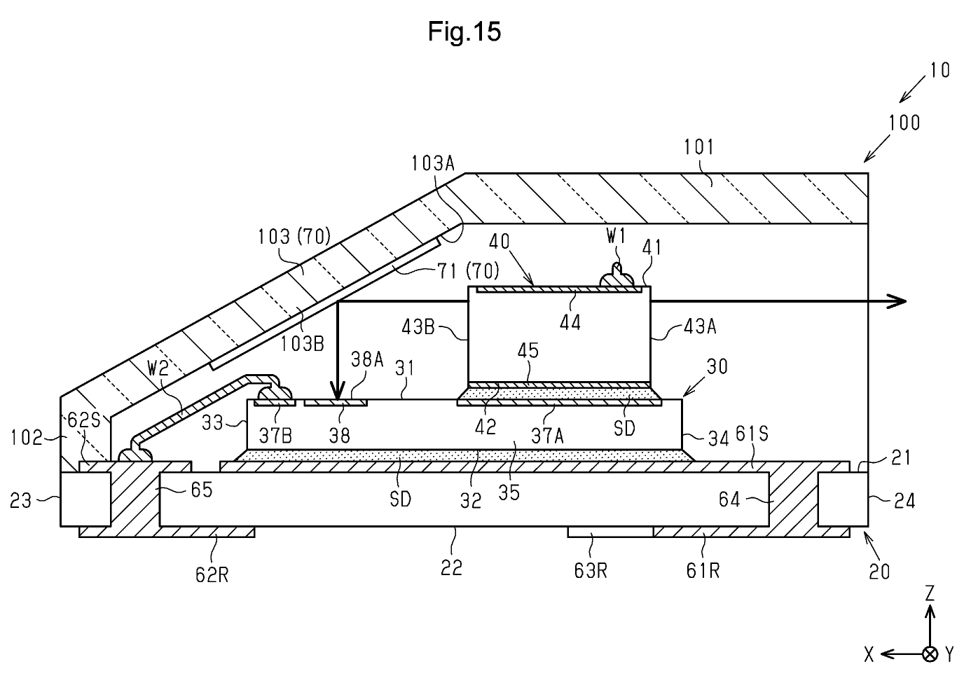

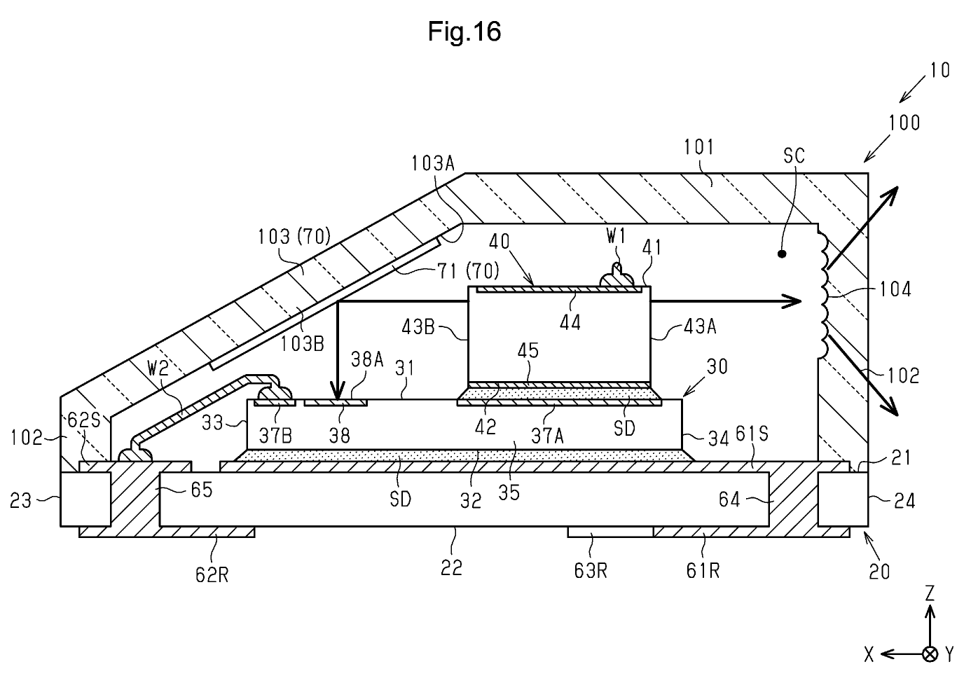

In the eighth embodiment, the structure of the case 100 may be changed. In an example, the case 100 may have a structure of a first example shown in FIG. 15 or a structure of a second example shown in FIG. 16.

As shown in FIG. 15, in the first example, one of the four side walls 102 that faces the first light-emitting surface 43A of the edge-emitting chip 40 may be omitted from the case 100. The side wall 102 facing the first light-emitting surface 43A is a side wall that extends along the second substrate side surface 24 of the substrate 20 in plan view. With this structure, the first laser beam from the first light-emitting surface 43A does not pass through the side wall 102. Therefore, the first laser beam is emitted out of the semiconductor light-emitting device 10 without being diffused by the side wall 102.

As shown in FIG. 16, in the second example, the case 100 may include a light-diffusing portion 104 configured to diffuse the first laser beam. The light-diffusing portion may be formed in one of the four side walls 102 that faces the first light-emitting surface 43A of the edge-emitting chip 40, that is, the side wall 102 through which the first laser beam passes. For example, the light-diffusing portion 104 is formed in a region of the side wall 102, through which the first laser beam passes, that faces the first light-emitting surface 43A in the X-direction. The light-diffusing portion 104 includes, for example, irregularities formed in an inner surface of the one of the four side walls 102 that faces the first light-emitting surface 43A of the edge-emitting chip 40. The irregularities forming the light-diffusing portion 104 include, for example, curved surfaces that are recessed from the inner surface of the side wall 102.

With this structure, the first laser beam is diffused by the light-diffusing portion 104, so that the directivity angle of the first laser beam is increased. As a result, the directivity angle of the laser beam from the semiconductor light-emitting device 10 is increased.

The region in which the light-diffusing portion 104 is formed may be changed. The light-diffusing portion 104 may be formed in a region that covers the entire first light-emitting surface 43A and is larger than the first light-emitting surface 43A as viewed in the X-direction. In an example, the light-diffusing portion 104 may be formed over the entire side wall 102, through which the first laser beam passes. The structure of the light-diffusing portion 104 may be changed as long as the first laser beam is diffused. In an example, the one of the four side walls 102 that faces the first light-emitting surface 43A of the edge-emitting chip 40 includes a flat surface and a rough surface. The flat surface corresponds to a portion of the inner surface of the side wall 102 excluding the region in which the light-diffusing portion 104 is formed. The rough surface corresponds to another portion of the inner surface of the side wall 102 that is located in the light-diffusing portion 104 and is rougher than the flat surface. The light-diffusing portion 104 includes the rough surface.

In the eighth embodiment, the reflection layer 71 may be formed on the outer surface of the inclined part 103 opposite to the inner surface 103A, instead of being formed on the inner surface 103A of the inclined part 103.

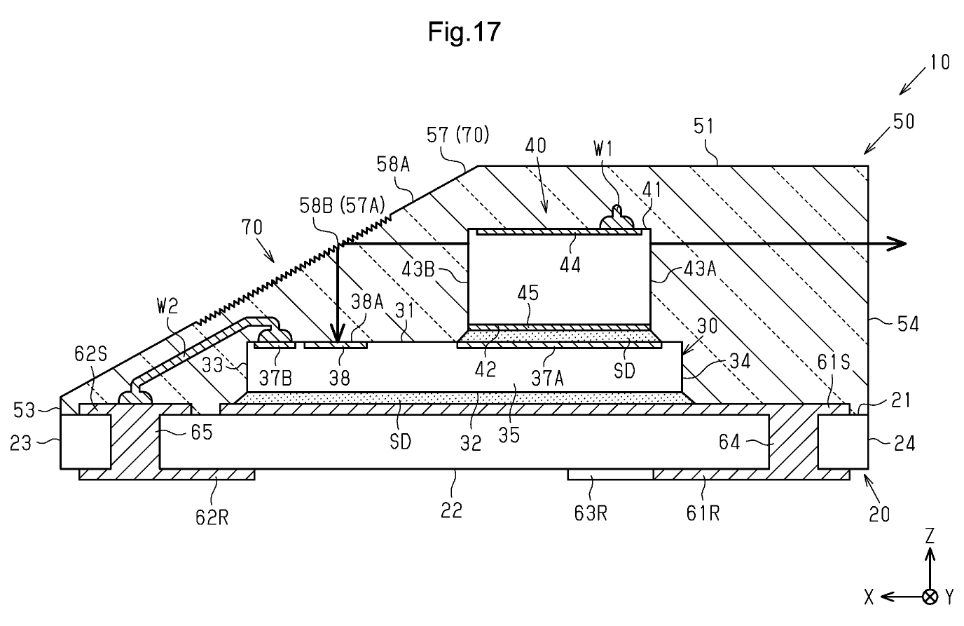

In the first to fourth and ninth embodiments, as shown in FIG. 17, the encapsulant 50 may include the reflector 70 in which irregularities are formed in the opposing region 57A of the edge-emitting chip 40, which faces the second light-emitting surface 43B. In the example shown in FIG. 17, the encapsulant 50 includes a flat surface 58A and a rough surface 58B that is rougher than the flat surface 58A. The opposing region 57A includes the rough surface 58B. The rough surface 58B may be formed over the entire opposing region 57A or in part of the opposing region 57A. That is, the rough surface 58B may be formed in at least part of the opposing region 57A.

Also, in the case 100 of the eighth embodiment, the reflector 70 may include irregularities formed in the opposing region 103B of the inner surface 103A of the inclined part 103. The opposing region 103B may include the rough surface 58B shown in FIG. 17.

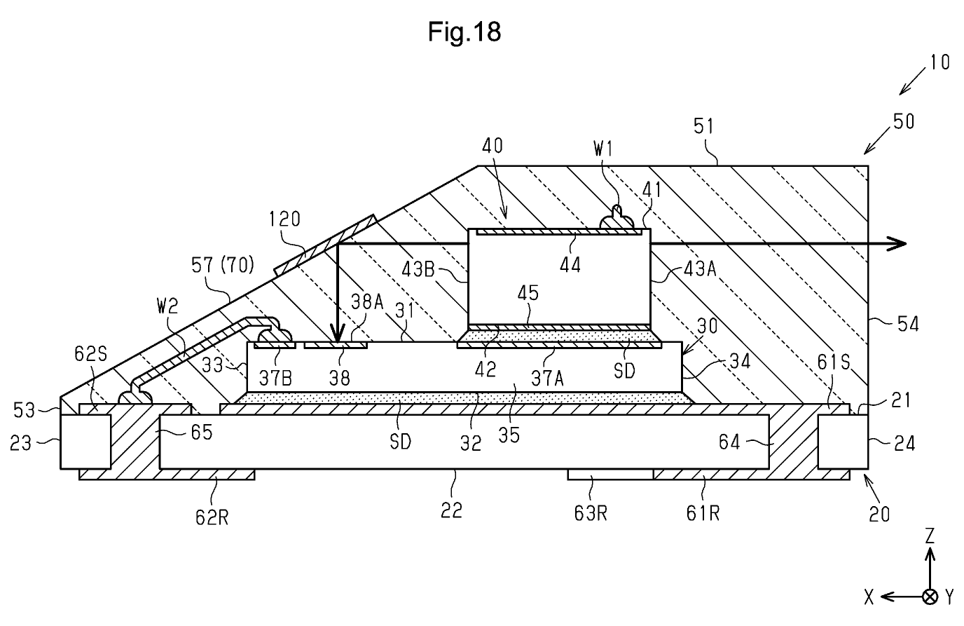

In the first, fourth, and ninth embodiments, as shown in FIG. 18, a light-blocking layer 120 may be included in the surface of the encapsulant 50 in the opposing region 57A. The light-blocking layer 120 covers, for example, the light-receiving surface 38A of the light-receiving element 38 as viewed in the thickness-wise direction of the substrate 20. The light-blocking layer 120 may be formed by, for example, a resin material that has a light-blocking property. An example of the light-blocking resin material is a black epoxy resin. Alternatively, the light-blocking layer 120 may be formed by, for example, a metal film. Alternatively, the light-blocking layer 120 may be formed by an anti-reflection coating (AR coating). The light-blocking layer 120 is, for example, rectangular as viewed in a direction orthogonal to the inclined surface 57. The shape of the light-blocking layer 120 as viewed in a direction orthogonal to the inclined surface 57 may be changed.

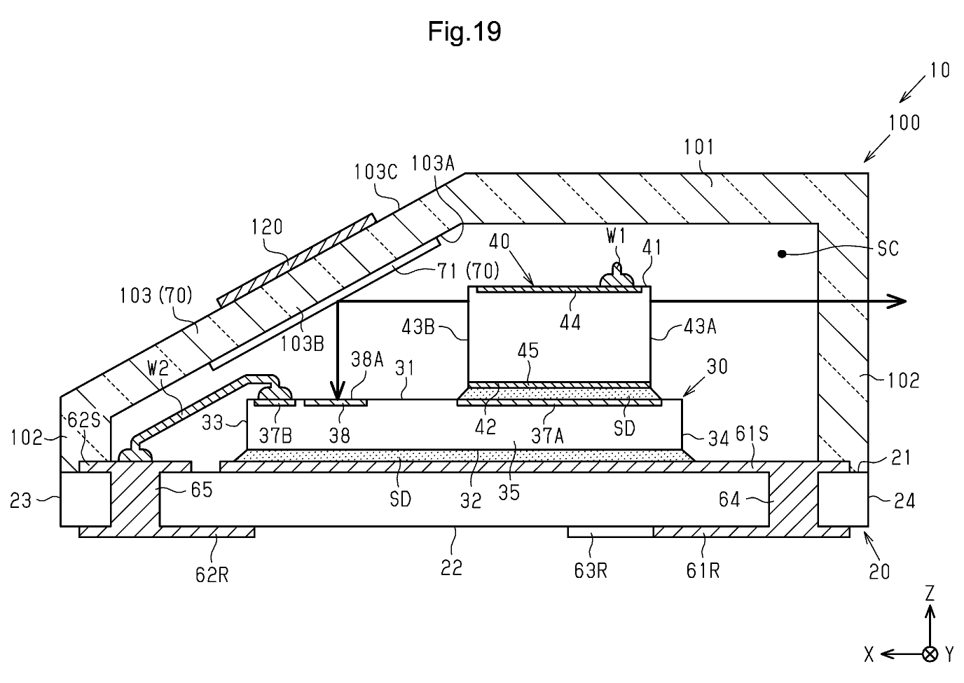

In the eighth embodiment, as shown in FIG. 19, the light-blocking layer 120 may be included in an outer surface 103C of the case 100 in the opposing region 103B. The light-blocking layer 120 covers, for example, the light-receiving surface 38A of the light-receiving element 38 as viewed in the thickness-wise direction of the substrate 20.

In the fifth to seventh embodiments, the light-blocking layer 120 may be included in the surface of the encapsulant 50. In this case, the light-blocking layer 120 covers, for example, the light-receiving surface 38A of the light-receiving element 38 as viewed in the thickness-wise direction of the substrate 20.

In the first to third and ninth embodiments, the inclined surface 57 of the encapsulant 50 does not have to be flat, and may be changed. In an example, the inclined surface 57 may be curved.

In the eighth embodiment, the inner surface 103A of the inclined part 103 of the case 100 does not have to be flat, but may be changed. In an example, the inner surface 103A of the inclined part 103 may be curved.

In the eighth embodiment, the case 100 accommodates the entire edge-emitting chip 40 and the entire light-receiving chip 30. However, there is no limit to such a structure. In an example, the case 100 may accommodate part of the edge-emitting chip 40 and part of the light-receiving chip 30, such that another part of the edge-emitting chip 40 and another part of the light-receiving chip 30 are located outside the case 100.

In the first to seventh and ninth embodiments, the material of the encapsulant 50 may be changed. In an example, the encapsulant 50 may be formed by a material that blocks a visible light ray and allows passage of a laser beam having a specific wavelength that differs from that of the visible light ray. The laser beam having a specific wavelength is, for example, an ultraviolet laser beam. The material of the encapsulant 50 may be, for example, a silicone encapsulant that blocks a visible light. Such an encapsulant may be, for example, AIR-7051-A/B (manufactured by Shin-Etsu Chemical Co., Ltd.). In this case, the edge-emitting chip 40 is configured to emit a laser beam having a specified wavelength. Further, the reflector 70 is configured to reflect the laser beam having the specific wavelength.

In the eighth embodiment, the material of the case 100 may be changed. In an example, the case 100 may be formed by a material that blocks a visible light ray and allows passage of a laser beam having a specific wavelength that differs from that of the visible light ray. The laser beam having a specific wavelength is, for example, an ultraviolet laser beam. The material of the case 100 may be, for example, a silicone encapsulant that blocks a visible light. Such an encapsulant may be, for example, AIR-7051-A/B (manufactured by Shin-Etsu Chemical Co., Ltd.). In this case, the edge-emitting chip 40 is configured to emit a laser beam having a specified wavelength. Further, the reflector 70 is configured to reflect the laser beam having the specific wavelength.

Various examples described in this specification may be combined as long as there is no technical contradiction.

Terms such as “first”, “second”, or “third” in this disclosure are used to distinguish subjects and are not used for ordinal purposes.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Accordingly, for example, a phrase such as “first element arranged on second element” may mean that the first element is directly located on the second element in one embodiment and that the first element is located above the second element without contacting the second element in another embodiment. Thus, the term “on” does not exclude a structure in which another component is formed between the first element and the second element.

The Z-direction as referred to in this disclosure does not necessarily have to be the vertical direction, and does not necessarily have to exactly coincide with the vertical direction. Accordingly, in the structures of the present disclosure, “up” and “down” with respect to the Z-direction as referred to in this specification are not limited to “up” and “down” with respect to the vertical direction. For example, the X-direction may be the vertical direction. Alternatively, the Y-direction may be the vertical direction.

### Clauses

Technical concepts that can be understood from the present disclosure will now be described. Reference characters used in the described embodiment are added to corresponding elements in the clauses to aid understanding without any intention to impose limitations on these elements. The reference characters are given as examples to aid understanding and are not intended to limit elements to the elements denoted by the reference characters.

Clause 1

A semiconductor light-emitting device (10), including: a substrate (20); a light-receiving chip (30) arranged on the substrate (20) and including a light-receiving element (38), the light-receiving element (38) including a light-receiving surface (38A) formed in a chip front surface (31) of the light-receiving chip (30); an edge-emitting chip (40) bonded to the chip front surface (31) at a position different from the light-receiving surface (38A) as viewed in a thickness-wise direction (Z-direction) of the substrate (20) and including a first light-emitting surface (43A) and a second light-emitting surface (43B), the first light-emitting surface (43A) being configured to emit a first laser beam in a first direction (X-direction) intersecting the thickness-wise direction (Z-direction) as viewed in the thickness-wise direction (Z-direction), the second light-emitting surface (43B) being configured to emit a second laser beam in a direction opposite to an emission direction of the first laser beam; a cover (50/100) formed on the substrate (20) by a material that allows passage of the first laser beam and the second laser beam, the cover (50/100) covering at least part of the edge-emitting chip (40) and at least part of the light-receiving chip (30); and a reflector (70) included in the cover (50/100), the reflector (70) being configured to reflect at least part of the second laser beam toward the light-receiving surface (38A), in which the light-receiving surface (38A) is formed in a position of the chip front surface (31) that receives at least part of a light reflected by the reflector (70).

Clause 2

A semiconductor light-emitting device (10), including: a substrate (20); a light-receiving chip (80) arranged on the substrate (20) and including a light-receiving surface formed in a front surface (81) of the light-receiving chip (80); a sub-mount substrate (90) arranged on the substrate (20); an edge-emitting chip (40) arranged on the sub-mount substrate (90) and including a first light-emitting surface (43A) and a second light-emitting surface (43B), the first light-emitting surface (43A) being configured to emit a first laser beam in a first direction (X-direction) intersecting a thickness-wise direction (Z-direction) of the substrate (20) as viewed in the thickness-wise direction (Z-direction), the second light-emitting surface (43B) being configured to emit a second laser beam in a direction opposite to an emission direction of the first laser beam; a cover (50/100) formed on the substrate (20) by a material that allows passage of the first laser beam and the second laser beam, the cover (50/100) covering the light-receiving chip (80), at least part of the sub-mount substrate (90), and at least part of the edge-emitting chip (40); and a reflector (70) included in the cover (50/100), the reflector (70) being configured to reflect at least part of the second laser beam toward the light-receiving chip (80), in which the light-receiving chip (80) is located at a position that receives at least part of a light reflected by from the reflector (70).

Clause 3

The semiconductor light-emitting device according to clause 1, in which the cover is an encapsulant (50) that encapsulates at least part of the edge-emitting chip (40) and at least part of the light-receiving chip (30).

Clause 4

The semiconductor light-emitting device according to clause 2, in which the cover is an encapsulant (50) that encapsulates the light-receiving chip (80), at least part of the sub-mount substrate (90), and at least part of the edge-emitting chip (40).

Clause 5

The semiconductor light-emitting device according to clause 3 or 4, in which the encapsulant (50) includes, as the reflector (70), an inclined surface (57) located at a side opposite to the first light-emitting surface (43A) with respect to the second light-emitting surface (43B) and inclined toward the light-receiving surface (38A) as the inclined surface (57) extends away from the edge-emitting chip (40) in the first direction (X-direction), and the light-receiving surface (38A) is located at a side opposite to the first light-emitting surface (43A) with respect to the second light-emitting surface (43B) in the first direction (X-direction) at a position that receives at least part of the second laser beam reflected by the inclined surface (57).

Clause 6

The semiconductor light-emitting device according to clause 5, in which the reflector (70) includes a reflection layer (71) formed on the inclined surface (57).

Clause 7

The semiconductor light-emitting device according to any one of clauses 3 to 6, in which the encapsulant (50) encapsulates the second light-emitting surface (43B) and exposes the first light-emitting surface (43A).

Clause 8

The semiconductor light-emitting device according to any one of clauses 3 to 7, in which the reflector (70) includes diffusers (72) arranged inside the encapsulant (50) and configured to diffuse the second laser beam.

Clause 9

The semiconductor light-emitting device according to clause 3, in which on the light-receiving chip (30), the encapsulant (50) encapsulates the second light-emitting surface (43B) and the light-receiving surface (38A) and exposes the first light-emitting surface (43A), and the reflector (70) includes diffusers (72) arranged inside the encapsulant (50) and configured to diffuse the second laser beam.

Clause 10

The semiconductor light-emitting device according to clause 1, in which the cover is a case (100) accommodating at least part of the edge-emitting chip (40) and at least part of the light-receiving chip (30).

Clause 11

The semiconductor light-emitting device according to clause 2, in which the cover is a case (100) accommodating the light-receiving chip (80), at least part of the sub-mount substrate (90), and at least part of the edge-emitting chip (40).

Clause 12

The semiconductor light-emitting device according to clause 10 or 11, in which the case (100) includes, as the reflector (70), an inclined part (103) located at a side opposite to the first light-emitting surface (43A) with respect to the second light-emitting surface (43B) and inclined toward the light-receiving surface (38A) as the inclined part (103) extends away from the edge-emitting chip (40) in the first direction (X-direction), and the light-receiving surface (38A) is located at a side opposite to the first light-emitting surface (43A) with respect to the second light-emitting surface (43B) in the first direction (X-direction) at a position that receives the second laser beam reflected by the inclined part (103).

Clause 13

The semiconductor light-emitting device according to clause 12, in which the reflector (70) includes a reflection layer (71) formed on the inclined part (103).

Clause 14

The semiconductor light-emitting device according to clause 13, in which the reflection layer (71) is formed on an inner surface (103A) of the inclined part (103).

Clause 15

The semiconductor light-emitting device according to any one of clauses 10 to 14, in which the case (100) includes a side wall (102) through which the first laser beam passes, and the side wall (102) includes a light-diffusing portion (104) configured to diffuse the first laser beam.

Clause 16

The semiconductor light-emitting device according to any one of clauses 1 to 5, in which the cover (50/100) includes an opposing region (57A/103B) facing the second light-emitting surface (43B), and the reflector (70) includes irregularities formed in the opposing region (57A/103B).

Clause 17

The semiconductor light-emitting device according to clause 16, in which the cover (50) includes a flat surface (58A) and a rough surface (58B) that is rougher than the flat surface (58A), and the opposing region (57A) includes the rough surface (58B).

Clause 18

The semiconductor light-emitting device according to any one of clauses 1 to 17, in which a light-blocking layer (120) is included in a surface of the cover (50/100) at a position facing the light-receiving surface (38A).

Clause 19

The semiconductor light-emitting device according to any one of clauses 1 to 18, in which the edge-emitting chip (40) is configured to emit the first laser beam and the second laser beam each having a specific wavelength that differs from that of a visible light ray, and the cover (50/100) is formed by a material that blocks the visible light ray and allows passage of the first laser beam and the second laser beam having the specific wavelength.

Clause 20

The semiconductor light-emitting device according to any one of clauses 1 to 5, in which the encapsulant (50) encapsulates the second light-emitting surface (43B) and exposes the first light-emitting surface (43A), the encapsulant (50) including an opposing region (57A) that faces the second light-emitting surface (43B), and the reflector (70) includes irregularities formed in the opposing region (57A).

Clause 21

The semiconductor light-emitting device according to clause 20, in which the encapsulant (50) includes a flat surface (58A) and a rough surface (58B) that is rougher than the flat surface (58A), and the opposing region (57A) includes the rough surface (58B).

Clause 22

A semiconductor light-emitting device (10), including: a substrate (20) including a substrate front surface (21) and a substrate back surface (22) facing opposite directions, and substrate side surfaces (23 to 26) connecting the substrate front surface (21) and the substrate back surface (22); an external terminal (111R to 113R) formed on one of the substrate side surfaces (23 to 26); a light-receiving chip (30) arranged on the substrate front surface (21) and including a light-receiving element (38), the light-receiving element (38) including a light-receiving surface (38A) formed in a chip front surface (31) of the light-receiving chip (30), the chip front surface (31) facing a same direction as the substrate front surface (21); an edge-emitting chip (40) bonded to the chip front surface (31) at a position different from the light-receiving surface (38A) as viewed in a thickness-wise direction (X-direction) of the substrate (20) and including a first light-emitting surface (43A) and a second light-emitting surface (43B), the first light-emitting surface (43A) being configured to emit a first laser beam in a first direction (Z-direction) intersecting the thickness-wise direction (X-direction) as viewed in the thickness-wise direction (X-direction), the second light-emitting surface (43B) being configured to emit a second laser beam in a direction opposite to an emission direction of the first laser beam; a cover (50/100) formed on the substrate front surface (21) by a material that allows passage of the first laser beam and the second laser beam, the cover (50/100) covering at least part of the edge-emitting chip (40) and at least part of the light-receiving chip (30); and a reflector (70) included in the cover (50/100), the reflector (70) being configured to reflect part of the second laser beam toward the light-receiving surface (38A), in which the light-receiving surface (38A) is formed in a position of the chip front surface (31) that receives at least part of a light reflected by the reflector (70).

Clause 23

A semiconductor light-emitting device (10), including: a substrate (20) including a substrate front surface (21) and a substrate back surface (22) facing opposite directions, and substrate side surfaces (23 to 26) connecting the substrate front surface (21) and the substrate back surface (22); an external terminal (111R to 113R) formed on one of the substrate side surfaces (23 to 26); a light-receiving chip (80) arranged on the substrate front surface (21) and including a light-receiving surface formed in a front surface (81) of the light-receiving chip (80), the front surface (81) facing a same direction as the substrate front surface (21); a sub-mount substrate (90) arranged on the substrate front surface (21) and including a sub-mount front surface (91), the sub-mount substrate front surface facing the same direction as the substrate front surface (21); an edge-emitting chip (40) arranged on the sub-mount front surface (91) and including a first light-emitting surface (43A) and a second light-emitting surface (43B), the first light-emitting surface (43A) being configured to emit a first laser beam in a first direction (Z-direction) intersecting a thickness-wise direction (X-direction) of the sub-mount substrate (90) as viewed in the thickness-wise direction (X-direction), the second light-emitting surface (43B) being configured to emit a second laser beam in a direction opposite to an emission direction of the first laser beam; a cover (50/100) formed on the substrate front surface (21) by a material that allows passage of the first laser beam and the second laser beam, the cover (50/100) covering the light-receiving chip (80), at least part of the sub-mount substrate (90), and at least part of the edge-emitting chip (40); and a reflector (70) included in the cover (50/100), the reflector (70) being configured to reflect part of the second laser beam toward the light-receiving chip (80), in which the light-receiving chip (80) is located at a position that receives at least part of a light reflected by from the reflector (70).

Clause 24

The semiconductor light-emitting device according to any one of clauses 1 to 23, in which the light-receiving chip (30/80) includes a photodiode.

The above descriptions are merely exemplary. One skilled in the art may recognize further possible combinations and replacements of the elements and methods (manufacturing processes) in addition to those listed for purposes of describing the techniques of the present disclosure. All replacements, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor light-emitting device, comprising:
a substrate;
a light-receiving chip arranged on the substrate and including a light-receiving element, the light-receiving element including a light-receiving surface formed in a chip front surface of the light-receiving chip;
an edge-emitting chip bonded to the chip front surface at a position different from the light-receiving surface as viewed in a thickness-wise direction of the substrate and including a first light-emitting surface and a second light-emitting surface, the first light-emitting surface being configured to emit a first laser beam in a first direction intersecting the thickness-wise direction as viewed in the thickness-wise direction, the second light-emitting surface being configured to emit a second laser beam in a direction opposite to an emission direction of the first laser beam;
a cover formed on the substrate by a material that allows passage of the first laser beam and the second laser beam, the cover covering at least part of the edge-emitting chip and at least part of the light-receiving chip; and
a reflector included in the cover, the reflector being configured to reflect at least part of the second laser beam toward the light-receiving surface,
wherein the light-receiving surface is formed in a position of the chip front surface that receives at least part of a light reflected by the reflector.

2. A semiconductor light-emitting device, comprising:
a substrate;
a light-receiving chip arranged on the substrate and including a light-receiving surface formed in a front surface of the light-receiving chip;
a sub-mount substrate arranged on the substrate;
an edge-emitting chip arranged on the sub-mount substrate and including a first light-emitting surface and a second light-emitting surface, the first light-emitting surface being configured to emit a first laser beam in a first direction intersecting a thickness-wise direction of the substrate as viewed in the thickness-wise direction, the second light-emitting surface being configured to emit a second laser beam in a direction opposite to an emission direction of the first laser beam;
a cover formed on the substrate by a material that allows passage of the first laser beam and the second laser beam, the cover covering the light-receiving chip, at least part of the sub-mount substrate, and at least part of the edge-emitting chip; and
a reflector included in the cover, the reflector being configured to reflect at least part of the second laser beam toward the light-receiving chip,
wherein the light-receiving chip is located at a position that receives at least part of a light reflected by from the reflector.

3. The semiconductor light-emitting device according to claim 1, wherein the cover is an encapsulant that encapsulates at least part of the edge-emitting chip and at least part of the light-receiving chip.

4. The semiconductor light-emitting device according to claim 2, wherein the cover is an encapsulant that encapsulates the light-receiving chip, at least part of the sub-mount substrate, and at least part of the edge-emitting chip.

5. The semiconductor light-emitting device according to claim 3, wherein
the encapsulant includes, as the reflector, an inclined surface located at a side opposite to the first light-emitting surface with respect to the second light-emitting surface and inclined toward the light-receiving surface as the inclined surface extends away from the edge-emitting chip in the first direction, and
the light-receiving surface is located at a side opposite to the first light-emitting surface with respect to the second light-emitting surface in the first direction at a position that receives at least part of the second laser beam reflected by the inclined surface.

6. The semiconductor light-emitting device according to claim 5, wherein the reflector includes a reflection layer formed on the inclined surface.

7. The semiconductor light-emitting device according to claim 3, wherein the encapsulant encapsulates the second light-emitting surface and exposes the first light-emitting surface.

8. The semiconductor light-emitting device according to claim 3, wherein the reflector includes diffusers arranged inside the encapsulant and configured to diffuse the second laser beam.

9. The semiconductor light-emitting device according to claim 3, wherein
on the light-receiving chip, the encapsulant encapsulates the second light-emitting surface and the light-receiving surface and exposes the first light-emitting surface, and
the reflector includes diffusers arranged inside the encapsulant and configured to diffuse the second laser beam.

10. The semiconductor light-emitting device according to claim 1, wherein the cover is a case accommodating at least part of the edge-emitting chip and at least part of the light-receiving chip.

11. The semiconductor light-emitting device according to claim 2, wherein the cover is a case accommodating the light-receiving chip, at least part of the sub-mount substrate, and at least part of the edge-emitting chip.

12. The semiconductor light-emitting device according to claim 10, wherein
the case includes, as the reflector, an inclined part located at a side opposite to the first light-emitting surface with respect to the second light-emitting surface and inclined toward the light-receiving surface as the inclined part extends away from the edge-emitting chip in the first direction, and
the light-receiving surface is located at a side opposite to the first light-emitting surface with respect to the second light-emitting surface in the first direction at a position that receives the second laser beam reflected by the inclined part.

13. The semiconductor light-emitting device according to claim 12, wherein the reflector includes a reflection layer formed on the inclined part.

14. The semiconductor light-emitting device according to claim 13, wherein the reflection layer is formed on an inner surface of the inclined part.

15. The semiconductor light-emitting device according to claim 10, wherein
the case includes a side wall through which the first laser beam passes, and
the side wall includes a light-diffusing portion configured to diffuse the first laser beam.

16. The semiconductor light-emitting device according to claim 1, wherein
the cover includes an opposing region facing the second light-emitting surface, and
the reflector includes irregularities formed in the opposing region.

17. The semiconductor light-emitting device according to claim 16, wherein
the cover includes a flat surface and a rough surface that is rougher than the flat surface, and
the opposing region includes the rough surface.

18. The semiconductor light-emitting device according to claim 1, wherein a light-blocking layer is included in a surface of the cover at a position facing the light-receiving surface.

19. The semiconductor light-emitting device according to claim 1, wherein
the edge-emitting chip is configured to emit the first laser beam and the second laser beam each having a specific wavelength that differs from that of a visible light ray, and
the cover is formed by a material that blocks the visible light ray and allows passage of the first laser beam and the second laser beam having the specific wavelength.
